(19) United States
(12) Patent Application Publication
(10) Pub. No.: US 2020/0185624 A1
(43) Pub. Date: Jun. 11, 2020

(54) Organic Electronic Component Having a Charge-Carrier Generation Layer

(71) Applicant: OSRAM OLED GmbH, Regensburg (DE)

(72) Inventors: Dominik Pentlehner, Burghausen (DE); Niels Gerlitzki, Neutraubling (DE); Florian Kessler, Wachenroth (DE); Anna Maltenberger, Leutenbach (DE); Günter Schmid, Hemhofen (DE); Sabine Szyszkowski, Dachsbach (DE); Dimitrios Zevgitis, Nürnberg (DE)

(73) Assignees: OSRAM OLED GmbH, Regensburg (DE); OSRAM OLED GmbH, Regensburg (DE)

(21) Appl. No.: 16/093,569

(22) PCT Filed: Apr. 11, 2017
(86) PCT No.: PCT/EP2017/058650

§ 371 Date: Oct. 12, 2018

(30) Foreign Application Priority Data
Apr. 14, 2016 (DE) 102016106917.5

(51) Int. Cl. H01L 51/00

(52) U.S. Cl. CPC H01L 51/0077; H01L 51/5008; H01L 51/0078

(57) ABSTRACT

An organic electronic device having a charge carrier generation layer is disclosed. In an embodiment an organic electronic device includes a first organic functional layer stack, a second organic functional layer stack and a charge carrier generation layer arranged therebetween, the charge carrier generation layer including an n-conducting region, an organic p-doped region and an intermediate region arranged therebetween, wherein the organic p-doped region has as a p-type dopant a fluorinated sulfonimide metal salt.

This patent application is a national phase filing under section 371 of PCT/EP2017/058650, filed Apr. 11, 2017, which claims the priority of German patent application 10 2016 106 917.5, filed Apr. 14, 2016, each of which is incorporated herein by reference in its entirety.

### TECHNICAL FIELD

The invention relates to an organic electronic device with a charge carrier generation layer.

### BACKGROUND

Charge carrier generation layers are referred to in English as “charge generation layers” or “CGLs” for short. They are of great importance in the field of organic electronics and can be used in various devices such as organic light emitting diodes or organic field effect transistors. They are often used in devices for the conversion of electric current into electromagnetic radiation.

High-performance organic electronic devices require charge carrier generation layers that allow good charge carrier separation and efficient transport of the charge carriers to the layers adjacent to the charge carrier generation layer.

In order for the charge carrier generation layer to fulfill these tasks, it requires more efficient p-type dopants. Not all p-type dopants which are suitable for conductivity doping are also suitable for their use in a charge carrier generation layer, since a charge-pair separation which is not achieved with all p-type dopants is essential for this application.

### SUMMARY OF THE INVENTION

Embodiments of the invention provide an organic electronic device having a charge carrier generation layer comprising a p-type dopant, which permits good conductivity and efficient charge carrier separation in the charge carrier generation layer.

According to one embodiment, an organic electronic device comprising a first and a second organic functional layer stack is specified. Between the first and the second organic functional layer stacks a charge carrier generation layer is arranged. The charge carrier generation layer comprises an organic p-doped region. The organic p-doped region comprises as p-type dopant a fluorinated sulfonimide metal salt.

The fact that one layer is “arranged between two other layers” can mean here and in the following that the one layer is arranged directly in direct mechanical and/or electrical contact with one of the two other layers. Alternatively, it may also mean that the one layer is disposed in indirect contact with one of the two other layers and in direct mechanical and/or electrical contact or in indirect contact with other layers. In the case of indirect contact, further layers can then be arranged between the one and at least one of the two other layers.

According to at least one embodiment, the charge carrier generation layer comprises an n-conducting region, a doped organic p-doped region and an intermediate region arranged therebetween, or the charge carrier generation layer consists of these layers.

According to at least one embodiment, the intermediate region is designed as an intermediate layer and has a layer thickness between 0.1 nm and 20 nm, preferably between 0.5 nm and 10 nm. The inventors have found that in this region of the layer thickness sufficiently high tunnel currents can be achieved for a good efficiency of the device and at the same time a good separation of the n-conducting and the p-doped region can be achieved, so that the materials of these do not react with each other. Intermediate layers of this layer thickness thus allow good efficiency and at the same time a high stability of the charge carrier generation layer and thus of the device containing it. Even more preferred is a layer thickness of 1 nm to 8 nm and most preferred is a layer thickness of 2 to 6 nm, for example, 4 nm. The balance between efficiency and lifetime is particularly pronounced in these regions.

According to at least one embodiment, the organic p-doped region comprises as p-type dopant a fluorinated sulfonimide metal salt of the following formula 1:

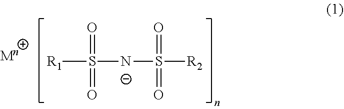

M is either a divalent or higher valent metal with an atomic mass of greater than 26 g/mol or a monovalent metal with an atomic mass of greater than or equal to 39 g/mol. In this case, n indicates the valence of M and it holds that 1≤n≤7, R1 and R2 can be selected independently of each another. R1 and R2 may be selected from the following group or combinations thereof: a fluoro-substituted aryl group, a fluoro-substituted alkyl group, a fluoro-substituted arylalkyl group.

In other words, the organic p-doped region of the charge carrier generation layer comprises a fluorinated sulfonimide metal salt, for example, a metal cation and one or more sulfonimide anions. The sulfonimide anion is simply negatively charged. The metal cation is n-times positively charged and requires correspondingly n fluorinated sulfonimide anions to form a neutral metal salt. In particular, n has a value of 1 inclusive to 4 inclusive, more preferably from 1 inclusive to 2 inclusive. Higher valent metal cations can in particular have a better doping effect because the Lewis acidic character is more pronounced. Rather undesirable are, in particular, oxidizing cations, such as Fe3+.

The organic electronic device can be, for example, an organic diode, an organic field-effect or bipolar transistor, an organic photodetector or an organic solar cell or organic electrochemical cell.

It may also be an organic electronic device that converts electrical current into electromagnetic radiation.

In the following, the term of the charge carrier generation layer will first be explained.

Organic light-emitting diodes (OLEDs) are an example of such devices. In OLEDs, electrons (as negative charge carriers) are provided by a cathode and “holes” (as positive charge carriers) from the side of the anode, which recombine in the region of an emitter layer located therebetween. As a result, photons and thus electromagnetic radiation are emitted. The use of charge carrier generation layers makes it possible, for example, to stack two or more such organic light-emitting diodes one above the other and to connect them in series. For this purpose, a charge carrier generation layer is arranged in each case between two OLEDs or two organic functional layer stacks. An organic electronic device formed in this way is often referred to as a tandem OLED and may have two or more OLED units stacked on top of each other or organic functional layer stacks. In this case, the charge carrier generation layer acts as a source of positive and negative charges for the connected OLEDs or organic functional layer stacks. It thus assumes equally the function within the organic electronic device as an inner anode for the one OLED or the first organic functional layer stack and an inner cathode for the other OLED or the second organic functional layer stack, thus enabling the OLEDs or layer stacks arranged one above the other to be connected in series.

This principle is not limited to OLEDs arranged one above the other, but generally applicable for organic electronic devices. Charge carrier generation layers can serve as charge carrier suppliers within organic electronic devices according to embodiments of the invention, one side of the charge carrier generation layer providing positive and the opposite side of the layer providing negative charge carriers.

Therefore, charge carrier generation layers have their name because charge carrier pairs of positive and negative charge carriers are formed in these layers and separated from one another. This is done at a so-called p-n junction (referred to in English as “p-n-heterojunction”). Charge carrier generation layers have a hole-transporting and an electron-transporting region for this purpose. The hole-transporting region of devices according to embodiments of the invention contains a fluorinated sulfonimide metal salt as p-type dopant and can therefore be described as an organic p-doped region. The electron conducting region may be described as the n-conducting region. Between the p-doped region and the n-conducting region an intermediate region is arranged. As a rule, the p-doped region has an energetically high LUMO (lowest unoccupied molecular orbital) and an energetically high HOMO (highest occupied molecular orbital, thus highest occupied molecular orbital). In contrast, the energy of LUMO and HOMO in the adjacent n-conducting region is generally comparatively low in each case. By way of example, when an external voltage is applied, an electron from the HOMO of the p-doped region can be tunneled via the intermediate region into the LUMO of the n-conducting region. The intermediate region forms an additional tunnel barrier. The tunneling leads to the separation of a charge carrier pair. In the p-doped region, a positive charge, in the n-conducting region a negative charge is obtained. The positive charge is then transported under the influence of the applied electric field through the p-doped region. The negative charge is transported analogously through the n-conducting region.

In addition to the charge carrier generation layer, the organic electronic device according to embodiments of the invention can have a cathode and an anode, wherein the charge carrier generation layer is arranged between the cathode and the anode. In particular, the first and second functional layer stacks are arranged between cathode and anode and the charge carrier generation layer is arranged between the first and second functional layer stacks. Furthermore, the device can have additional layers, in particular in the organic functional layer stacks, as they are common in conventional organic electronic devices.

The organic p-doped region of the charge carrier generation layer contains the fluorinated sulfonimide metal salt according to embodiments of the invention as p-type dopant. For example, the organic p-doped region may additionally comprise a matrix material. In particular, it is possible that the organic p-doped region contain both a matrix material and the p-type dopant, wherein the p-type dopant may be incorporated into the matrix material. For example, the p-type dopant can be present homogeneously, thus evenly distributed in the matrix material. In particular, the fluorinated sulfonimide metal salt acts as an electron acceptor with respect to the matrix material. In particular, a coordinative bond with binding and antibinding orbital is formed.

For the purposes of embodiments of the invention, the term p-type dopant comprises or means in particular materials, with regard to the matrix material, which have at least partial or complete Lewis acidity or act as Lewis acid and/or are capable of forming bonds, in particular covalent, ionic or coordinative bonds with the matrix material in which these materials (even if only formally) act as Lewis acid.

The inventors of the present invention have discovered that the fluorinated sulfonimide metal salts of embodiments of the invention are surprisingly useful as p-type dopant in charge carrier generation layers. In contrast, so far only zinc complexes are known as p-type dopants based on Lewis-acidic metal complexes, which at the same time fulfill all other necessary conditions for use in charge carrier generation layers such as suitable processability, stability of the doped layers and sufficiently low absorption. Surprisingly, the fluorinated sulfonimide metal salts according to embodiments of the invention, which are Lewis acids, meet all the necessary requirements for use in charge carrier generation layers.

Thus, the inventors have observed that the p-type dopants according to embodiments of the invention, due to their good p-type dopant strength, allow very good conductivities, in particular hole conductivities in organic p-doped regions. Matrix materials doped with the fluorinated sulfonimide metal salts exhibit excellent conductivities as required for use in hole injection or hole transport layers in organic electronic devices. Accordingly, the fluorinated sulfonimide metal salts of embodiments of the invention may additionally be present in hole or hole injection layers of the first and/or second organic functional layer stacks. Such good hole transport properties are of central importance for the p-doped region of a charge carrier generation layer. The positive charge carriers are transported through the organic p-doped region after formation at the p-n junction and finally injected into the adjacent layers. For this purpose, good hole conductivities of the p-doped region, as achieved with the fluorinated sulfonimide metal salts according to embodiments of the invention, are essential.

However, while a number of metal complexes form suitable p-type dopants, there are very few materials that satisfy the second central requirement for p-type dopants in a charge carrier generation layer. In order for charge separation to occur at all, a tunnel current must occur at the p-n junction, thus a tunneling of electrons from the HOMO of the p-doped region through the intermediate region into the LUMO of the n-conducting region. When using commercially available standard materials for the n-conducting region, the choice of the p-type dopant is decisive for whether the charge separation takes place sufficiently efficient or not. The reason for this is that the p-dopant has a decisive influence on the energetic position of the molecular orbitals on the side of the p-doped region and thus on the relative position of the energy levels involved in the transition. The choice of the p-type dopant is therefore central to the question of achieving sufficient tunnel currents. If it is possible to generate sufficient tunnel currents, the “CGL effect” is referred to as the charge carrier generation layer effect. Only then are the prerequisites for efficient charge carrier separation and thus the “generation” of charge carriers for the adjacent organic functional layer stacks given.

The inventors of the present invention have found that the fluorinated sulfonimide metal salts according to embodiments of the invention surprisingly enable high tunnel currents at p-n junctions and are thus suitable for charge carrier generation layers.

Furthermore, the fluorinated sulfonimide metal salts according to embodiments of the invention have a particularly low absorption in the visible light range. They are therefore characterized by a very good radiation permeability and are therefore particularly suitable, for example, for use in optoelectronic devices, for example, for organic light-emitting diodes.

In addition, the fluorinated sulfonimide metal salts of embodiments of the invention also have good thermal stability and are easily evaporated or easily sublimated. They show a uniform evaporation behavior during deposition in layers from the gas phase. In addition, they can be deposited in one layer together with a matrix material without great technical effort, for example, by means of co-evaporation.

The comparatively high stability of the fluorinated sulfonimide metal salts, whose decomposition temperature is generally significantly higher than their evaporation temperature, allows a simple production of the p-doped region of the charge carrier generation layer by means of gas phase deposition. However, the fluorinated sulfonimide metal salts can also be processed as part of a liquid phase separation. The good stability and evaporation simplifies the production of organic electronic devices with the charge carrier generation layer according to embodiments of the invention.

According to at least one embodiment, M is selected from a group: copper, zinc, aluminum, bismuth, potassium, rubidium, cesium, scandium, yttrium and tin, preferably copper, zinc or potassium, more preferably zinc or copper. Alternatively or additionally, the residues R1 and/or R2 may each be a trifluoromethane. Fluorinated sulfonimide metal salts, thus in particular trifluoromethanesulfonimide metal salts (TFSI) can be generated, such as Sn(TFSI)4, Zn(TFSI)2, Cu(TFSI)2 and K(TFSI). These metal salts are commercially available and particularly easily accessible. The inventors have recognized that these commercially available metal salts can improve electrical properties of organic matrix materials, in particular organic hole conductors, when the matrix materials are doped with the metal salts. In addition, they enable a very efficient charge separation in a charge carrier generation layer.

The fluorinated sulfonimide metal salts according to embodiments of the invention do not belong to the salts of superacids, since the corresponding acids of the sulfonimide metal salts have an acid constant value pkS>−3, preferably pkS>0. Superacids in particular have a pKs value of <−3. A decisive advantage compared to metal salts of superacids is that the fluorinated sulfonimide metal salts are vaporizable without decomposition and can thus be made available in the required high purity by sublimation and used in the vacuum process.

According to at least one embodiment, the residues R1 and R2 are independently selected from the following group: a linear or branched, at least partially fluorine-substituted alkyl residue having 1 to 10 carbon atoms, an at least partially fluoro-substituted aryl residues having 1 to 20 carbon atoms or an at least partially fluoro-substituted arylalkyl residue with 1 to 20 carbon atoms. Alternatively, the above-described alkyl residues, aryl residues and arylalkyl residues can also be completely substituted by fluorine and thus be perfluorinated.

According to at least one embodiment, R₁ and R₂ are the same substituents and selected from the following group:

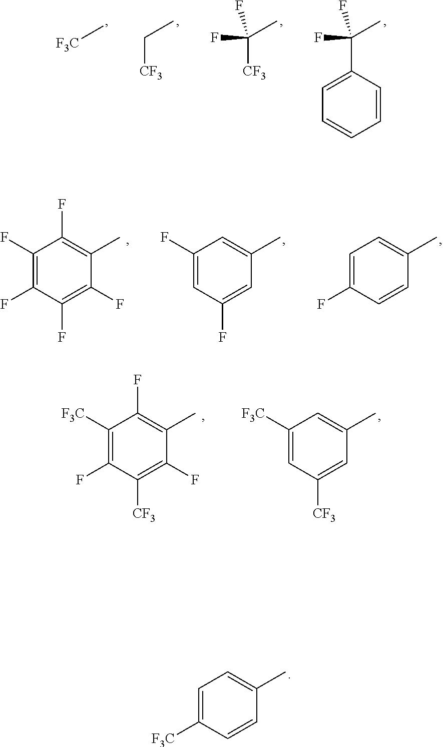

According to at least one embodiment, the sulfonimide anion is selected from the following group:

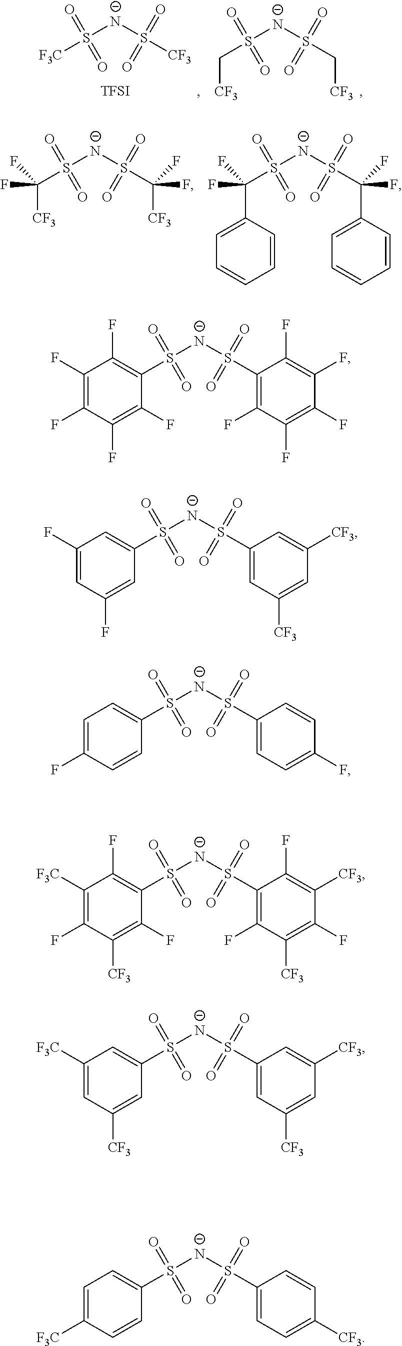

According to at least one embodiment, the sulfonimide anion is preferably selected from the following group:

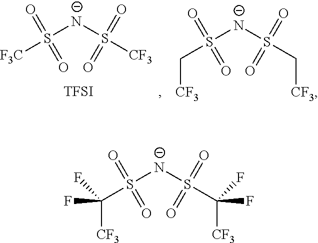

The formulas for the sulfonimide anion shown above should only be exemplary and serve to illustrate. These sulfonimide anions are not intended to limit the scope of the invention. In the context of embodiments of the invention, a plurality of identical or even different fluorinated sulfonimide anions may be bonded to a metal center Mn+. The coordination of individual sulfonimide anions may also be different. For example, an anion may simply be bound to the metal via oxygen. Alternatively, the bonding can also be done twice over different oxygen atoms. Also, the bonding via a nitrogen or sulfur of the fluorinated sulfonimide anion is conceivable. In this case, the metal salt can form an ionic bond and/or a complex compound. For example, the coordination of the sulfonimide anion can be via two oxygen atoms to the metal. This can also be called chelation.

According to at least one embodiment, M is selected from the group of divalent or higher valent metals having an atomic mass of greater than 26 g/mol. In particular, the positive charge on the metal can assume a value between 2 and 7, inclusive and is compensated in particular by n single negative charged perfluorinated sulfonimide anions. Preferably, n assumes a value between 2 inclusive and 4 inclusive. N is preferably 2. The residues R1 and R2 are in particular a linear or branched partially or completely fluorinated alkyl substituent having 1 to 10 carbon atoms, a partially or completely fluorinated aryl substituent having 1 to 20 carbon atoms or a partially or completely fluorinated arylalkyl substituent with 1 up to 20 carbon atoms.

According to at least one embodiment, M is selected from the group of monovalent metals having an atomic mass ≥39 g/mol. In particular, the positive charge on the metal assumes a value of 1 and is compensated in particular by a singly negatively charged perfluorinated sulfonimide anion. The residues R1 and R2 are in particular selected from the group consisting of a linear or branched partially or completely fluorinated alkyl substituent of 1 to 10 carbon atoms, a partially or completely fluorinated aryl substituent of 1 to 20 carbon atoms and a partially or completely fluorinated alkylaryl substituent of 1 to 20 carbon atoms.

According to a preferred embodiment, the p-type dopant comprises a fluorinated sulfonimide metal salt of the following formula 2:

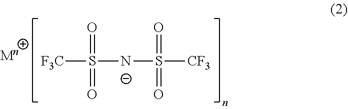

M is either a divalent or higher valent metal with an atomic mass of greater than 26 g/mol or a monovalent metal with an atomic mass of greater than or equal to 39 g/mol. n indicates the valence of M and the following applied: 1≤n≤7.

According to a particularly preferred embodiment, the p-type dopant comprises a fluorinated sulfonimide metal salt of one of the following formulas:

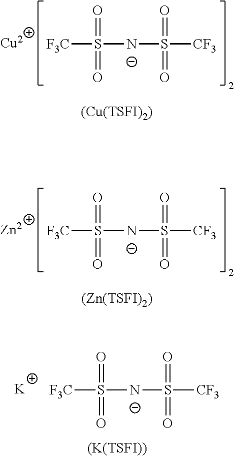

In particular, Cu(TSFI)2 or Zn(TSFI)2 prove to be particularly efficient as p-type dopants in charge carrier generation layers. Initial measurements show an efficiency equivalent to Novaled's known p-type dopant NDP9 in terms of hole conductivity and charge separation. The p-dopants are commercially available and significantly cheaper than NDP9.

A particularly preferred embodiment of the organic electronic is characterized by an organic p-doped region, which is an organic p-doped layer. The p-doped layer may in particular be a continuous, area-covering layer.

According to at least one embodiment, the one organic p-doped layer has a layer thickness between 1 nm and 300 nm, preferably between 5 nm and 150 nm, particularly preferably between 10 nm and 100 nm, for example, 40 nm.

A preferred embodiment of the organic electronic device is characterized by an organic p-doped region which has an organic hole-conducting matrix into which the p-type dopant is introduced. In particular, the fluorinated sulfonimide metal salt can therefore be homogeneously distributed uniformly in the matrix material. For example, the p-doped region may be achieved by co-evaporation of the fluorinated sulfonimide metal salt and the matrix-forming material. So a particularly homogeneous distribution is achievable.

According to one embodiment, the p-doped region may consist of the p-type dopant and the matrix material.

Particularly suitable as matrix materials for the p-doped region of the charge carrier generation layer are materials with good hole transport properties, which are also easy to process and can be doped with the fluorinated sulfonimide metal salt without great technical effort.

According to a preferred embodiment, the p-doped region of the charge carrier generation layer can be produced in the gas phase as well as the liquid phase. In the vapor deposition both p-type dopant and matrix material are evaporated together, preferably from different sources in a high vacuum and deposited as a layer. In the liquid phase processing, the fluorinated sulfonimide metal salt and the matrix material are dissolved in a solvent and deposited by means of printing techniques, spin coating, knife coating, slot coating, etc. The finished layer is obtained by evaporation of the solvent. Due to the different mass ratios of p-type dopant to the matrix material, any doping ratios can be set.

With particular preference, the following hole-conducting matrix materials for the p-doped region of the charge carrier generation layer can be processed by means of a solvent process:

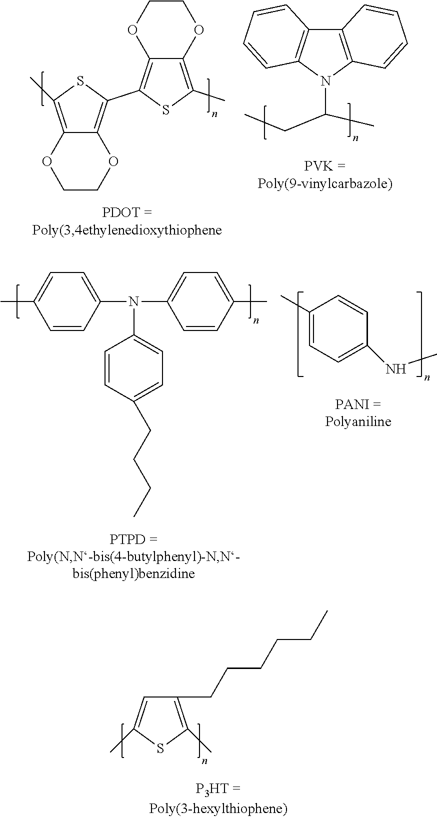

In addition, matrix materials which are referred to as “small molecules” can be processed particularly preferably by means of a solvent process. This class of substances is known to the expert and includes, for example, spiro-TAD (2,2′,7,7′-tetrakis-(N,N-diphenylamino)-9,9′-spirobifluorene) and spiro-TTB (2,2′,7,7′-tetrakis (N,N′-di-p-methylphenylamino)-9,9′-spirobifluorene) and other materials as listed in this application as matrix materials.

A particularly preferred embodiment of the organic electronic device has an organic p-doped region which has one of the following organic matrix-forming materials with hole-conducting properties:

### NPB (N,N′-Bis(naphthalene-1-yl)-N,N′-bis(phenyl)benzidine),

### β-NPB N,N′-Bis(naphthalene-2-yl)-N,N′-bis(phenyl)benzidine),

TPD (N,N′-Bis(3-methylphenyl)-N,N′-bis(phenyl)-benzidine),
Spiro-TPD (N,N′-Bis(3-methylphenyl)-N,N′-bis(phenyl)-benzidine),
Spiro-NPB (N,N′-Bis(naphthalene-1-yl)-N,N′-bis(phenyl)-spiro),
DMFL-TPD N,N′-Bis(3-methylphenyl)-N,N′-bis(phenyl)-9,9-dimethyl-fluoren),
α-NPD N,N-Bis(naphthalene-1-yl)-N,N-bis(phenyl)-2,2′-dimethylbenzidine,
N,N′-Bis(3-methylphenyl)-N,N′-bis(phenyl)-2,7-diamino-9,9-spirofluorene,
N,N′-Bis(naphthalene-1-yl)-N,N′-bis(phenyl)-2,7-diamino-9,9-spirofluorene,
DMFL-NPB (N,N′-Bis(naphthalene-1-yl)-N,N′-bis(phenyl)-9,9-dimethyl-fluorene),
DPFL-TPD (N,N′-Bis(3-methylphenyl)-N,N′-bis(phenyl)-9,9-diphenyl-fluorene),
DPFL-NPB (N,N′-Bis(naphthalene-1-yl)-N,N′-bis(phenyl)-9,9-diphenyl fluorene),
Spiro-TAD (2,2′,,7′-Tetrakis(N,N-diphenylamino)-9,9′-spirobifluorene),
9,9-Bis[4-(N,N-bis-biphenyl-4-yl-amino)phenyl]-9H-fluorene,
NPAPF 9,9-Bis[4-(N,N-bis-naphthalene-2-yl-amino)phenyl]-9H-fluorene,
NPBAPF 9,9-Bis[4-(n-naphthalene-1-yl-N-phenylamino)-phenyl]-9H-fluorene,
9,9-Bis[4-(N,N′-bis-naphthalene-2-yl-N,N′-bis-phenyl-amino)phenyl]-9H-fluorene,
PAPB N,N′-Bis(phenanthrene-9-yl)-N,N′-bis(phenyl)-benzidine,
2,7-Bis[N,N-bis(9,9-spiro-bifluorene-2-yl)-amino]-9,9-spiro-bifluorene,
2,2′-Bis[N,N-bis(biphenyl-4-yl)amino]9,9-spiro-bifluorene,
2,2′-Bis(N,N-di-phenyl-amino)9,9-spiro-bifluorene,
Di-[4-(N,N-ditolyl-amino)-phenyl]cyclohexane,
2,2′,7,7′-Tetra(N,N-di-tolyl)amino-spiro-bifluorene,
N,N,N,N′,N′-Tetra-naphthalene-2-yl-benzidine,
Spiro-2NPB 2,2′,7,7′-Tetrakis[n-naphthalenyl(phenyl)-amino]-9,9-spirobifluorene,
Spiro-TTB (2,2′,7,7′-Tetrakis-(N,N′-di-p-methylphenylamino)-9,9′-spirobifluorene),
TiOPC titanium oxide phthalocyanine,
CuPC Copper phthalocyanine,
F4-TCNQ 2,3,5,6-tetrafluoro-7,7,8,8-tetracyano-quinodimethane
4,4′,4″-Tris(N-3-methylphenyl-N-phenyl-amino)triphenylamine
4,4′,4″-Tris(N-(2-naphthyl)-N-phenyl-amino)triphenylamine
4,4′,4″-Tris(N-(1-naphthyl)-N-phenyl-amino)triphenylamine

### 4,4′,4″-Tris(N,N-diphenylamino)triphenylamine

PPDN Pyrazino[2,3-f][1,10]phenanthroline-2,3-dicarbonitrile
MeO-TPD N,N,N,N′,N′-tetrakis(4-methoxyphenyl)benzidine
Spiro-MeOTAD N²,N²,N²′,N²′,N^{7,}N^{7,}N^{7,}N⁷′,N⁷′-octakis(4-methoxyphenyl)-9,9′-spirobi[9H-fluorene]-2,2′,7,7′-tetramine.

However, the possible matrix materials for the organic p-doped region of the charge carrier generation layer are not limited to the materials mentioned. Other matrix materials such as, for example, commercially available NHT5, NHT49, NHT51 from Novaled, HTM014, HTM081, HTM163 from Merck, EL-301 and EL-022T from Hodogaya and similar commercially available materials are also suitable. These hole-conducting matrix materials have proven useful and allow particularly good electrical properties for the p-doped region of the charge carrier generation layer.

According to another preferred embodiment, the matrix materials or matrix-forming materials are materials from the group of triarylamines and/or materials from the group of spiro compounds. They are preferably materials which have both a triaryl group and a spiro center.

According to a preferred embodiment of the invention, the degree of doping in volume % of the fluorinated sulfonimide metal salt relative to the p-doped region in volume % is from ≥0.1% to ≤20%. This has proven to be useful. Preferably, the degree of doping is from ≥1 vol. % to ≤20 vol. %, more preferably ≥2 vol. % to ≤15 vol. %, even more preferably 2 vol. % to ≤10 vol. % and most preferably ≥3 vol. % to ≤6 vol. %. Measurements by the inventors prove that in these areas the conductivities most suitable for an application in organic electronic devices, e.g., OLEDs, can be achieved. In addition, it has been found that sufficiently high tunnel currents at p-n junctions can be obtained in these areas.

According to at least one embodiment, the n-conducting region is an organic n-conducting region. Preferably, the n-conducting region may be an n-conducting layer, in particular an area-covering, continuous layer.

According to at least one embodiment, the intermediate region is designed as an intermediate layer, in particular as an area-covering, continuous intermediate layer. At the p-n junction with intermediate region, the charge carrier pair separation takes place. The p-doped region may be a p-doped layer and, at the same time, the n-conducting region may be an n-conducting layer, with an intermediate region in the form of an intermediate layer between the p-doped layer and the n-conducting layer.

An embodiment of the device has an organic n-doped region as the n-conducting region.

The organic n-doped region preferably has an electron-conducting matrix and an n-type dopant which is introduced into the electron-conducting matrix. In particular, the n-type dopant may be homogeneously distributed in the electron-conducting matrix. The n-doped region can preferably be produced by coevaporation of a matrix-forming material and the n-type dopant. For example, the n-doped region may be an n-doped layer. For example, the n-doped region may consist of the n-type dopant and the electron-conducting matrix.

According to a further preferred embodiment, the organic n-conducting region has a matrix, in particular an electron-conducting matrix. For example, the electron-conducting matrix may be doped with an n-type dopant, but a sufficiently conductive matrix is also conceivable without n-type dopant. The material for the electron-conducting matrix of the n-conducting region and/or the n-conducting layer may be selected from a group which includes the commercially available matrix materials:

NET-18, NET-218 from Novaled,
LG-201 from LG Chem,
ET093, ET156, ET165 from Idemitsu Kosan,
ETM020, ETM033, ETM034, ETM036 from Merck.

In addition, the material for the electron-conducting matrix of the n-conducting region and/or the n-conducting layer may be selected from the group of the following materials:

2,2′,2″-(1,3,5-Benzenetriyl)tris(1-phenyl-1-H-benzimidazole),
2-(4-Biphenylyl)-5-(4-tert-butylphenyl)-1,3,4-oxadiazole,
2,9-Dimethyl-4,7-diphenyl-1,10-phenanthroline (BCP),

### 8-Hydroxyquinolinolato-lithium,

4-(Naphthalene-1-yl)-3,5-diphenyl-4H-1,2,4-triazole,
1,3-Bis[2-(2,2′-bipyridine-6-yl)-1,3,4-oxadiazo-5-yl]benzene, 4,7-Diphenyl-1,10-phenanthroline (BPhen),
3-(4-Diphenylyl) -4-phenyl-5-tert-butylphenyl-1,2,4-triazole, Bis(2-methyl-8-quinolinolate)-4-(phenylphenolato)aluminum, 6,6′-Bis[5-(biphenyl-4-yl)-1,3,4-oxadiazo-2-yl]-2,2′-bipyridyl,

### 2-Phenyl-9,10-di(naphthalene-2-yl)anthracene,

2,7-Bis[2-(2,2′-bipyridine-6-yl)-1,3,4-oxadiazo-5-yl]-9,9-dimethylfluorene,
1,3-Bis[2-(4-tert-butylphenyl)-1,3,4-oxadiazo-5-yl]benzene, 2-(Naphthalene-2-yl)-4,7-diphenyl-1,10-phenanthroline,
2,9-Bis(naphthalene-2-yl)-4,7-diphenyl-1,10-phenanthroline, Tris(2,4,6-trimethyl-3-(pyridine-3-yl)phenyl)borane,

### 1-Methyl-2-(4-(naphthalene-2-yl)phenyl)-1H-imidazo[4,5-f][1,10]phenanthroline,

Phenyl-dipyrenylphosphine oxides, Naphthalenetetracarboxylic dianhydride and its imides, perylenetetracarboxylic dianhydride and its imides, materials based on silols having a silacyclopentadiene moiety. Also possible are mixtures of the above substances.

According to a preferred embodiment, the n-conducting region and/or the n-conducting layer has as n-type dopant one or more materials selected from a group consisting of LiQ (lithium quinolate), LiF, NDN-1, NDN-26 from Novaled, Na, Ca, Mg, Ag, Cs, Li, Mg, Yb, Cs₂CO₃ and Cs₃PO₄.

These materials are characterized by the necessary electrical properties for use in the n-conducting region. Deposition of the electron-conducting matrix and the n-type dopant is possible by evaporation or sublimation by gas phase processes. If an n-type dopant is present, which is preferred, the deposition can be done by co-evaporation. However, a separation can also take place by means of liquid processing.

According to at least one embodiment, the intermediate region is arranged directly, thus in direct mechanical and/or electrical contact to the n-conducting region, as well as to the p-doped region. The intermediate region thus has a common interface with the p-doped region and a common interface with the n-conductive region. In particular, the n-conducting region and the organic p-doped region are connected to each other via the intermediate region. With the help of the intermediate region, it is possible to avoid undesired reactions between the organic p-doped region and the n-conducting region. In this way, a very stable charge carrier generation layer and thus a very stable device can be provided.

Various materials can be used to design the intermediate region. The intermediate region may comprise or consist of insulating, organic and inorganic materials. Some suitable embodiments are given below as examples.

The intermediate region, for example, designed as an intermediate layer, may contain insulating materials, for example, aluminum oxide, or be formed from them. In this case, the intermediate layer represents a tunneling barrier for the charge carriers. At the same time, the intermediate layer separates the n-conducting region and the p-doped region, which otherwise could react with one another at the interface and thereby lose their function in the device.

The intermediate region may also comprise organic materials or be formed from organic materials (thus an organic intermediate region or an organic intermediate layer) which have intermediate states which increase the tunneling probability. The charge carriers can then move between the p-doped region and the n-conducting region next to the “tunneling” in addition by the so-called hopping mechanism of intermediate state to intermediate state of the material of the organic intermediate layer. As a result, the efficiency of the device can be increased. In this case, the stabilizing effect of the intermediate region can be used and efficiency can be improved at the same time.

The intermediate region may also comprise or consist of an inorganic material. The inorganic intermediate region, for example, designed as an inorganic intermediate layer, has a second charge carrier transport mechanism. The second charge carrier transport mechanism transports the charge carriers by “tunneling”, thus it represents a tunnel barrier for the charge carriers. The second charge carrier transport mechanism has no hopping mechanism compared to the first charge carrier transport mechanism since the materials of the inorganic intermediate layer have no intermediate states that induce a hopping mechanism. Thus, the first charge carrier transport mechanism at least partially differs from the second charge carrier transport mechanism. Also in this case, the intermediate area has a positive effect on the stability of the device.

According to at least one embodiment, the intermediate region is an organic intermediate region.

The organic intermediate region comprises, according to an embodiment, a material or combination of materials selected from a group consisting of phthalocyanine, at least one or exactly one phthalocyanine derivative, naphthalocyanine, at least one or exactly one naphthalocyanine derivative, porphyrin and at least one or exactly one porphyrin derivative. The phthalocyanine derivative may be, in particular, vanadyl phthalocyanine.

According to at least one embodiment, the organic intermediate region comprises or consists of at least one phthalocyanine and/or a phthalocyanine derivative. The phthalocyanine and/or phthalocyanine derivative is each coordinated to a metal or a metal compound. The metal or metal compound is selected from a group consisting of copper (Cu), zinc (Zn), cobalt (Co), aluminum (Al), nickel (Ni), iron (Fe), tin oxide (SnO), manganese (Mn), magnesium (Mg), vanadium oxide (VO) and titanium oxide (TiO) comprises or consists of. The phthalocyanine derivative may be, in particular, vanadyl phthalocyanine.

The materials disclosed in DE 10 2013 107 113 A1 and/or DE 10 2013 017 361 A1 and/or DE 10 2012 204 327 A1 can be used for the organic intermediate region. The disclosure content of the above mentioned disclosure requirements is hereby incorporated by reference.

According to at least one embodiment, the intermediate region is an inorganic intermediate region. The inorganic intermediate region comprises at least one metal or semi-metal selected from the group consisting of lithium (Li), sodium (Na), potassium (K), rubidium (Rb), cesium (Cs), beryllium (Be), magnesium (Mg), calcium (Ca), strontium (Sr), barium (Ba), boron (B), aluminum (Al), silver (Ag), ytterbium (Yb), gallium (Ga), indium (In), thallium (Tl) and combinations thereof, comprises or consists thereof.

According to at least one embodiment, the inorganic intermediate region comprises at least one metal or semi-metal selected from the group consisting of lithium (Li), sodium (Na), potassium (K), rubidium (Rb), cesium (Cs), beryllium (Be), magnesium (Mg), calcium (Ca), strontium (Sr), barium (Ba), boron (B), aluminum (Al), silver (Ag), ytterbium (Yb), gallium (Ga), indium (In), thallium (Tl) and combinations thereof, comprises or consists thereof.

According to at least one embodiment, the inorganic intermediate region comprises or consists of a non-noble metal. In particular, the inorganic intermediate region is set up as an n-type dopant. Preferably, the inorganic intermediate layer is formed of calcium and/or calcium is established as an n-type dopant. Calcium increases the band bending at the interface, this means, it acts as an n-type dopant at the interface n-conducting region and at the same time separates the electron-conducting and hole-conducting organic layers from each other, this means, it acts as an insulator.

According to a further embodiment, the intermediate region may comprise or consist of two intermediate layers, wherein the first intermediate layer is different from the second intermediate layer in its material. The prerequisite is that the layer thickness of both layers together does not exceed 20 nm, preferably 10 nm, since otherwise no “tunneling through” of the charge carriers can take place.

According to at least one embodiment, the device has at least two electrodes, an anode and a cathode, with which a voltage can be applied to the device.

According to one embodiment, when an external voltage is applied, the emitter layers of the organic functional layer stacks can emit electromagnetic radiation in the form of visible light, infrared light or UV light, for example. The device is then a radiation-emitting device, in particular an organic light-emitting diode.

According to at least one embodiment, at least one of the electrodes is transparent. Here and in the following, “transparent” refers to a layer that is transparent to visible light. In this case, the transparent layer can be clearly translucent or at least partially light-scattering and/or partially light-absorbing, so that the transparent layer can also be translucent, for example, diffuse or milky. Particularly preferred is a layer designated here as transparent as possible transparent, so that in particular the absorption of light generated during operation of the organic electronic device in the emitter layers is as low as possible.

According to at least one embodiment, both electrodes are transparent. In this way, the light generated in the at least two emitter layers can be radiated in both directions, thus through both electrodes. In the case where the organic electronic device has a substrate, this means that the light can be emitted both through the substrate, which is then also transparent, and in the direction away from the substrate. Furthermore, in this case, all layers of the organic electronic device can be made transparent, so that the device forms a transparent OLED. In addition, it may also be possible for one of the two electrodes, between which the emitter layers and the charge carrier generation layer are arranged is not transparent and preferably reflective, so that the light generated in the at least two emitter layers can only be radiated in one direction through the transparent electrode. In particular, this direction is the main beam direction or main direction x. If the electrode on the substrate is transparent and if the substrate is also transparent, it is also referred to as a so-called bottom emitter, while in the case if the electrode facing away from the substrate is transparent, it is referred to as a so-called top emitter.

According to at least one embodiment, one electrode is transparent and the further electrode is designed to be reflective, so that the radiation generated in the emitter layers is coupled out in the main direction via the transparent electrode. In particular, the electrode formed as transparent is arranged on a substrate, which is then also transparent. The device is then formed as a so-called bottom emitter.

As material for a transparent electrode a transparent conductive oxide may be used, for example. Transparent conductive oxides (“TCO” for short) are usually metal oxides such as zinc oxide, tin oxide, cadmium oxide, titanium oxide, indium oxide or indium tin oxide (ITO). In addition to binary metal oxygen compounds, such as ZnO, SnO2 or In2O3, ternary metal oxygen compounds, such as Zn2SnO4, CdSnO3, ZnSnO3, MgIn2O4, GaInO3, Zn2In2O5 or In4Sn3O12 or mixtures of different transparent conductive oxides, also belong to the group of TCOs. The TCOs do not necessarily correspond to a stoichiometric composition and may still be p- or n-doped. In particular, the transparent material is indium tin oxide (ITO).

A preferred embodiment has the following arrangement: The first organic functional layer stack comprising the first emitter layer is arranged on the anode, the charge carrier generation layer is arranged on the first organic functional layer stack and the second organic functional layer stack comprising the second emitter layer is arranged on the charge carrier generation layer. The cathode is finally arranged on the second organic functional layer stack.

The fact that a layer is arranged, produced or applied “on” or “above” another layer may here and in the following mean that the one layer is arranged, produced or applied directly in direct mechanical and/or electrical contact on the other layer. Furthermore, it can also mean that the one layer is arranged, produced or applied indirectly on or above the other layer. In this case, further layers can then be arranged between the one and the other layer.

It is also possible, for example, that the device has a substrate, which may be applied, for example, to the outside of the cathode or anode, in particular in the direct vicinity of the cathode or anode. For example, the anode can be arranged directly on the substrate.

In at least one embodiment, the n-conducting region of the charge carrier generation layer is arranged on the side of the charge carrier generation layer facing the anode and the p-doped region is arranged on the side of the charge carrier generation layer facing the cathode.

The arrangement described represents an electronic device in which two organic functional layer stacks, also known as OLED subunits, are connected in series by means of the charge carrier generation layer. This allows higher luminance levels to be achieved with the same current. Such devices in particular allow longer lifetimes than conventional organic light-emitting diodes and at the same time more homogeneous luminance.

According to one embodiment, the cathode comprises aluminum, copper or silver.

Suitable electrode materials are also AgMg alloys.

According to a further embodiment, the anode has a material selected from the group comprising indium tin oxide (ITO) and aluminum zinc oxide (abbreviated to AZO). The anode can also consist of a material from said group.

According to another embodiment of the invention, the first and second emitter layers each independently comprise a matrix material and in each case independently of one another, an emitter material. These may in each case be common materials used in emitter layers.

Suitable materials for the emitter material are materials which have a radiation emission due to fluorescence or phosphorescence. Preferred organic materials are organic or organometallic compounds, such as derivatives of polyfluorene, polythiophene and polyphenylene, for example, 2- or 2,5-substituted poly-p-phenylenevinylene) and/or metal complexes, for example, iridium complexes, such as blue phosphorescent FIrPic (Bis(3,5-difluoro-2-(2-pyridyl)phenyl-(2-carboxypyridyl)iridiumIII), green phosphorescing Ir(ppy)3 (Tris(2-phenylpyridine)iridiumIII) and/or red phosphorescent Ru (dtb-bpy)3*2(PF6)(Tris[4,4′-di-tert-butyl-(2,2′)-bipyridine]ruthenium(III) complex), as well as blue fluorescent DPAVBi (4,4-Bis[4-(di-p-tolylamino)styryl]biphenyl), green fluorescent TTPA (9,10-Bis[N,N-di(p-tolyl)amino]anthracene) and/or red fluorescent DCM2 (4-Dicyanomethylene)-2-methyl-6-ylolidyl-9-enyl-4H-pyran) as non-polymeric emitters.

In a further development, both emitter layers are identical. However, it is preferred if the emitter layers emit electromagnetic radiation of different wavelengths, thus if the emitter layers are different. This allows color mixtures to be achieved with the radiation emitted by the device. For example, an emitter layer may also contain two emitter materials which emit radiation of different wavelengths. Together with the second emitter layer, for example, white light can be generated.

According to at least one embodiment, the organic electronic device has a substrate. In particular, one of the two electrodes is arranged on the substrate. The substrate may comprise, for example, one or more materials in the form of a layer, a plate, a foil or a laminate, which are selected from glass, quartz, plastic, metal, silicon, wafers. In particular, the substrate comprises or consists of glass.

Above the anode and the cathode, preferably above the cathode, an encapsulation arrangement can be arranged which can protect the electrodes and the further layers from harmful external influences such as moisture, oxygen, hydrogen sulfide or other substances. Preferably, the encapsulation arrangement is in direct mechanical contact with the cathode.

According to at least one embodiment, the first organic functional layer stack comprises a hole injection layer, an electron blocking layer, a hole transport layer and/or a hole blocking layer. The use of such layers has been proven in organic electronic devices. In particular, the hole injection layer on the anode, the electron blocking layer and/or hole transport layer on the hole injection layer, the first emitter layer on the electron blocking layer and/or hole transport layer, the hole blocking layer on the first emitter layer and the charge carrier generation layer are arranged on the hole blocking layer. In particular, there is a direct mechanical and/or electrical contact between the hole-blocking layer of the first organic functional layer stack and the n-conducting region of the charge carrier generation layer.

According to at least one embodiment, the second organic functional layer stack has an electron injection layer, a hole blocking layer, an electron transport layer and/or an electron blocking layer. The use of such layers has been proven in organic electronic devices. In particular, the electron blocking layer is disposed on the charge carrier generation layer, the second emitter layer on the electron blocking layer, the hole blocking layer and/or electron transport layer on the second emitter layer, the electron injection layer on the hole blocking layer and/or electron transport layer, and the cathode on the electron injection layer. In particular, there is a direct mechanical and/or electrical contact between the electron blocking layer of the second organic functional layer stack and the organic p-doped region of the charge carrier generation layer.

The material for a hole injection layer may be selected from a group comprising

### HAT-CN, F16CuPc, LG-101, α-NPD,

NPB (N,N′-Bis(naphthalene-1-yl)-N,N′-bis(phenyl)-benzidine), beta-NPB N,N′-Bis(naphthalene-2-yl)-N,N′-bis(phenyl)-benzidine),
TPD (N,N′-Bis(3-methylphenyl)-N,N′-bis(phenyl)-benzidine), Spiro TPD (N,N′-Bis(3-methylphenyl)-N,N′-bis(phenyl)-benzidine),
Spiro-NPB (N,N′-Bis(naphthalene-1-yl)-N,N′-bis(phenyl)-spiro), DMFL-TPD N,N′-Bis(3-methylphenyl)-N,N′-bis(phenyl)-9,9-dimethyl-fluorene),
DMFL-NPB (N,N′-Bis(naphthalene-1-yl)-N,N′-bis(phenyl)-9,9-dimethyl-fluorene),
DPFL-TPD (N,N′-Bis(3-methylphenyl)-N,N′-bis(phenyl)-9,9-diphenyl-fluorene),
DPFL-NPB (N,N′-Bis(naphthalene-1-yl)-N,N′-bis(phenyl)-9,9-diphenyl-fluorene),
Spiro-TAD (2,2′,7,7′-Tetrakis(N,N-diphenylamino)-9,9′-spirobifluorene),
9,9-Bis[4-(N,N-bis-biphenyl-4-yl-amino)phenyl]-9H-fluorene, 9,9-Bis[4-(N,N-bis-naphthalene-2-yl-amino)phenyl]-9H-fluorene, 9,9-Bis[4-(N,N′-bis-naphthalene-2-yl-N,N′-bis-phenyl-amino)-phenyl]-9H-fluorene
N,N′-Bis(phenanthrene-9-yl)-N,N′-bis(phenyl)-benzidine,
2,7-Bis[N,N-bis(9,9-spiro-bifluorene-2-yl)-amino]-9,9-spiro-bifluorene,
2,2′-Bis[N,N-bis(biphenyl-4-yl)amino]9,9-spiro-bifluorene, 2,2′-Bis(N,N-di-phenyl-amino)9,9-spiro-bifluorene, Di-[4-(N,N-ditolyl-amino)-phenyl]cyclohexane,
2,2′,,7′-tetra(N, N-di-tolyl)amino-spiro-bifluorene, N,N,N′,N′-tetra-naphthalene-2-yl-benzidine,
HTM081, HTM163, HTM222, NHT49, NHT51 and mixtures of these compounds.

Alternatively, the hole injection layer may comprise the p-type dopant according to the invention or may consist in particular of the p-type dopant, thus the fluorinated sulfonimide metal salt.

As p-type dopant for the hole injection layer, there may be used one or more materials selected from a group consisting of MoOₓ, WOₓ, VOₓ, Cu(I)pFBz (pFBz: Pentafluorobenzoate), Bi(III)pFBz, F4-TCNQ (2,3,5,6-Tetrafluoro-7,7,8,8-tetracyanoquinodimethane), NDP-2 and NDP-9. The terms HTM081, HTM163, HTM222, NHT49, NHT51, NET-18, NET-218, ET093, ETM020, ETM033, ETM034, ETM036, NDN-1, the fluorinated sulfonimide metal salt according to the descriptions above and NDN-26 are manufacturer names for products of Merck, Novaled and/or Idemitsu.

The material for an electron injection layer may be selected from a group comprising NET-18, NET-218, ET093, ETM020, ETM033, ETM034, ETM036, LG-201, ET156, ET165,

2,2′,2″-(1,3,5-Benzinetriyl)-tris(1-phenyl-1-H-benzimidazole),
2-(4-Biphenylyl)-5-(4-tert-butylphenyl)-1,3,4-oxadiazole, 2,9-Dimethyl-4,7-diphenyl-1,10-phenanthroline (BCP),

### 8-Hydroxyquinolinolato-lithium,

4-(Naphthalene-1-yl)-3,5-diphenyl-4H-1,2,4-triazole,
1,3-Bis[2-(2,2′-bipyridine-6-yl)-1,3,4-oxadiazo-5-yl]benzene, 4,7-Diphenyl-1,10-phenanthroline (BPhen),
3-(4-Biphenylyl)-4-phenyl-5-tert-butylphenyl-1,2,4-triazole, Bis(2-methyl-8-quinolinolate)-4-(phenylphenolato)aluminum, 6,6′-Bis[5-(biphenyl-4-yl)-1,3,4-oxadiazo-2-yl]-2,2′-bipyridyl, 2-Phenyl-9,10-di(naphthalene-2-yl)-anthracene,
2,7-Bis[2-(2,2′-bipyridine-6-yl)-1,3,4-oxadiazo-5-yl]-9,9-dimethylfluorene,
1,3-Bis [2-(4-tert-butylphenyl)-1,3,4-oxadiazo-5-yl]benzene,
2-(naphthalen-2-yl)-4,7-diphenyl-1,10-phenanthroline,
2,9-Bis(naphthalene-2-yl)-4,7-diphenyl-1,10-phenanthroline, Tris(2,4,6-trimethyl-3-(pyridin-3-yl)phenyl)borane,
1-methyl-2-(4-(naphthalene-2-yl)phenyl)-1H-imidazo[4,5-f][1,10]phenanthroline,
Phenyl dipyrenylphosphinoxide, Naphtahlinetetracarboxylic dianhydride and its imides,
Perylenetetracarboxylic dianhydride and its imides, materials based on silols with a Silacyclopentadiene moiety and mixtures of the aforementioned substances. The n-type dopant may be one or more materials selected from the group consisting of LiQ (lithium quinolate), LiF, NDN-1, NDN-26, Na, Ca, Mg, Ag, Cs, Li, Mg, Yb, Cs₂CO₃ and Cs₃PO₄.

A suitable material for an electron blocking layer is, for example:

2,2′,2″-(1,3,5-Benzinetriyl)-tris(1-phenyl-1-H-benzimidazole),
2-(4-Biphenylyl)-5-(4-tert-butylphenyl)-1,3,4-oxadiazole,
2,9-Dimethyl-4,7-diphenyl-1,10-phenanthroline,

### 8-Hydroxyquinolinolato-lithium,

4-(Naphthalene-1-yl)-3,5-diphenyl-4H-1,2,4-triazole,
1,3-Bis[2-(2,2′-bipyridine-6-yl)-1,3,4-oxadiazo-5-yl]benzene,
4,7-Diphenyl-1,10-phenanthroline,
3-(4-Biphenylyl)-4-phenyl-5-tert-butylphenyl-1,2,4-triazole,
Bis(2-methyl-8-quinolinolate)-4-(phenylphenolato)aluminum,
6,6′-Bis[5-(biphenyl-4-yl)-1,3,4-oxadiazo-2-yl]-2,2′-bipyridyl,
2-Phenyl-9,10-di(naphthalene-2-yl)-anthracene,
2,7-Bis[2-(2,2′-bipyridine-6-yl)-1,3,4-oxadiazo-5-yl]-9,9-dimethylfluorene,
1,3-Bis [2-(4-tert-butylphenyl)-1,3,4-oxadiazo-5-yl]benzene,
2-(naphthalene-2-yl)-4,7-diphenyl-1,10-phenanthroline,
Tris(2,4,6-trimethyl-3-(pridin-3-yl)phenyl)borane,
1-methyl-2-(4-(naphthalene-2-yl)phenyl)-1H-imidazo[4,5-f][1,10]phenanthroline.

Blocking and limiting the flow of electrons is of great importance, for example, for highly efficient organic light-emitting diodes.

Suitable materials for the hole transport layer are the hole-conducting matrix materials which are mentioned in relation to the organic p-doped region.

According to at least one embodiment, the electron blocking layer and/or hole transport layer may be constructed analogous to the organic p-doped region of the charge carrier generation layer. It can thus contain a fluorinated sulfonimide metal salt as p-type dopant and a matrix material according to the above-mentioned embodiments. In particular, in an electron blocking layer and/or hole transport layer, the p-type dopant has a proportion between inclusive 1 vol.-% and inclusive 50 vol.-%, preferably between inclusive 1 vol.-% and 30 vol.-%, more preferably between inclusive 2 vol.-% and inclusive 20 vol.-%.

As material for a hole blocking layer, for example

2,2′,2″ -(1,3,5-Benzinetriyl)-tris(1-phenyl-1-H-benzimidazole),
2-(4-Biphenylyl)-5-(4-tert-butylphenyl)-1,3,4-oxadiazole,
2,9-Dimethyl-4,7-diphenyl-1,10-phenanthroline (BCP),

### 8-Hydroxyquinolinolato-lithium,

4-(Naphthalene-1-yl)-3,5-diphenyl-4H-1,2,4-triazole,
1,3-Bis[2-(2,2′-bipyridine-6-yl)-1,3,4-oxadiazo-5-yl]benzol,
4,7-Diphenyl-1,10-phenanthroline (BPhen)1
3-(4-Biphenylyl)-4-phenyl-5-tert-butylphenyl-1,2,4-triazole,
Bis(2-methyl-8-quinolinolate)-4-(phenylphenolato)aluminum,
6,6′-Bis[5-(biphenyl-4-yl)-1,3,4-oxadiazo-2-yl]-2,2′-bipyridyl,
2-Phenyl-9,10-di(naphthalene-2-yl)-anthracene,
2,7-Bis[2-(2,2′-bipyridine-6-yl)-1,3,4-oxadiazo-5-yl]-9,9-dimethylfluorene,
1,3-Bis [2-(4-tert-butylphenyl)-1,3,4-oxadiazo-5-yl]benzol,
2-(naphthalene-2-yl)-4,7-diphenyl-1,10-phenanthroline,
2,9-Bis(naphthalene-2-yl)-4,7-diphenyl-1,10-phenanthroline,
Tris(2,4,6-trimethyl-3-(pyridin-3-yl)phenyl)borane,

### 1-Methyl-2-(4-(naphthalene-2-yl)phenyl)-1H-imidazo[4,5-f][1,10]phenanthroline,

Phenyl-dipyrenylphosphine oxid,
Naphtahlinetetracarboxylic dianhydrid and its imides
Perylenetetracarboxylic dianhydrid and its imides
Materials based on siloles with a Silacyclopentadiene moiety,
and mixtures of the aforementioned substances.

Suitable materials for the electron transport layer are the electron-conducting matrix materials which are mentioned in relation to the organic p-doped region.

According to one embodiment of the embodiments of the device described above, the device has at least one further charge carrier generation layer and at least one further organic functional layer stack comprising a further emitter layer. An arrangement of this type has a total of at least three emitter layers and at least two charge carrier generation layers. For example, the emitter layers can emit radiation of a different spectral range and thus permit color mixtures. In particular, such a white-light-emitting device can be made possible. However, it is also conceivable that two or even three of the emitter layers are identical and thus enable emission of particularly high luminances in a specific wavelength range.

### BRIEF DESCRIPTION OF THE DRAWINGS

Further advantages, advantageous embodiments and developments emerge from the embodiments described below in conjunction with the figures.

FIG. 1 schematically shows the principle of the charge carrier generation in a charge carrier generation layer;

FIGS. 2 to 5 show schematic representations of inventive organic electronic devices;

FIG. 6 shows the attachment of a fluorinated sulfonimide metal salt to a matrix material according to one embodiment;

FIG. 7 shows a fluorinated sulfonimide metal salt according to one embodiment;

FIGS. 8 to 11 show current-voltage characteristics of various devices;

FIG. 12A shows a schematic representation of a measurement arrangement for determining the suitability for the use of p-type dopants for charge carrier generation layers;

FIG. 12B shows a current-voltage characteristic as desired for a p-type dopant suitable for charge carrier generation layers;

FIGS. 13A to 13B show the current-voltage characteristics for Cu(TSFI)₂ as p-dopant introduced a matrix (HTM081 and NHT51, respectively);

FIGS. 14A to 14B show the current-voltage characteristics for Zn(TSFI)₂ as p-dopant introduced a matrix (HTM081 and NHT51, respectively); and

FIGS. 15A to 15C show characteristics of various embodiments of organic electronic devices.

### DETAILED DESCRIPTION OF ILLUSTRATIVE EMBODIMENTS

FIG. 1 shows a schematic representation of the principle of the charge carrier generation in a charge carrier generation layer. The scheme shows the energy levels as a function of place within a charge carrier generation layer. In the diagram, the energy (E) is plotted against the place (O). In the p-doped organic region 5a of the charge carrier generation layer, the LUMO (“lowest unoccupied molecular orbital”) and the HOMO (“highest occupied molecular orbital”) each have particularly high energy levels. In comparison, the energy levels of LUMO and HOMO within the n-conducting region 5b of the charge carrier generation layer are markedly lowered. The HOMO of the p-doped region 5a and the LUMO of the n-conducting region 5b are comparatively close in terms of energy. For this reason, under certain circumstances, for example, when an external voltage is applied, it is possible to tunnel an electron from the HOMO of the p-doped region 5a into the LUMO of the n-conducting region 5b of the charge carrier generation layer. The choice of the p-type dopant plays a central role in the position of the described energy levels and thus forms a central prerequisite for the occurrence of a tunnel current in the charge carrier generation layer. Through the described tunneling of an electron from the HOMO of the p-doped organic region 5a via an intermediate layer (not shown here) into the LUMO of the n-conducting region 5b, a charge carrier pair in the form of a positive charge remaining in the HOMO of the p-doped region 5a and an electron, thus a negative charge, in the LUMO of the n-conducting region 5b are produced and separated. The positive charge within the p-doped organic region 5a can be transported under the influence of an external electric field through the p-doped region 5a of the charge carrier generation layer, while in an analogous manner the negative charge, thus the electron, can be transported through the n-conducting region 5b of the charge carrier generation layer. Between the p-doped region 5a and the n-conducting region 5b, a thin intermediate layer (with a thickness of a few nanometers) is arranged (not shown here). This creates an additional barrier that also has to be “tunneled through”.

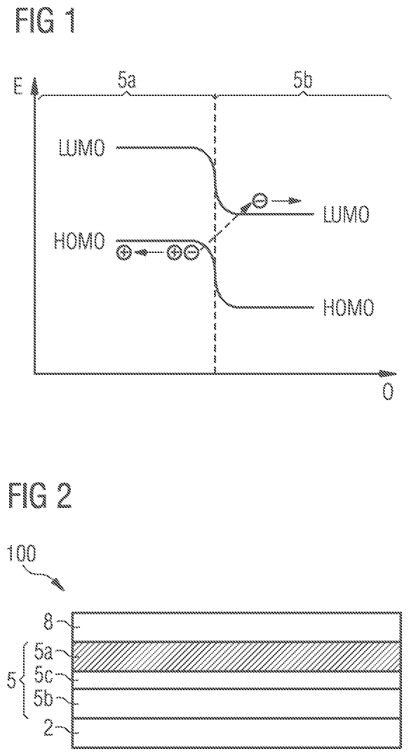

FIG. 2 shows a schematic representation of the layer arrangement in an organic electronic device 100 comprising at least one charge carrier generation layer 5. The charge carrier generation layer 5 comprises at least one organic p-doped region 5a containing the inventive fluorinated sulfonimide metal salt as p-type dopant. For example, the organic p-doped region 5a may comprise an organic hole-conducting matrix containing an organic hole-conducting matrix material in which the fluorinated sulfonimide metal salt is incorporated as a p-type dopant. The charge carrier generation layer 5 furthermore has an n-conducting region 5b, for example, designed as an organic n-doped region. Between the n-conducting region 5b and the p-doped region 5a, an intermediate region 5c is arranged. The intermediate region 5c is preferably designed as an intermediate layer. Also, the n-conducting region 5b and the p-doped region 5a are each preferably configured as layers. The device further comprises at least one anode 2 and one cathode 8, wherein the charge carrier generation layer 5 is arranged between anode 2 and cathode 8.

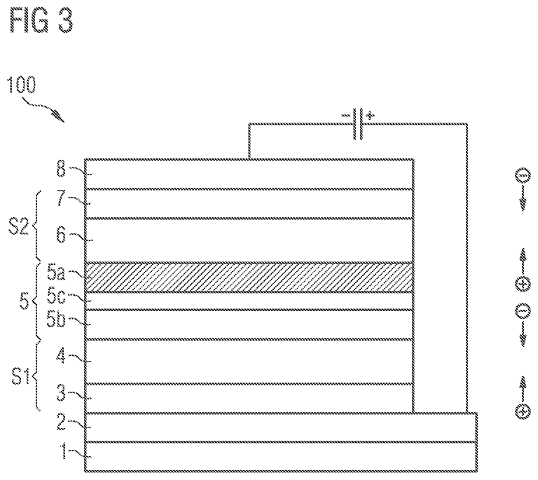

FIG. 3 illustrates a schematic representation of an embodiment of an organic electronic device 100. The device has a substrate 1, which may be, for example, a glass substrate. On the substrate 1, an anode 2 is arranged, which may contain, for example, indium tin oxide (ITO, “indium tin oxide”). On the anode 2, a first organic functional layer stack S1 is arranged. The layer stack S1 has a hole injection layer 3 arranged above the anode 2. Above the hole injection layer 3, a first emitter layer 4 is arranged. The first emitter layer 4 is designed to emit light in the visible range of the electromagnetic spectrum during operation of the device. Above the first organic functional layer stack S1, a charge carrier generation layer 5 is arranged. The charge carrier generation layer 5 consists of a p-doped organic region 5a, an intermediate region 5c, and an n-conducting region 5b. The n-conducting region 5b is arranged in direct mechanical contact with the first functional layer stack S1. The intermediate layer 5c is connected to the regions 5a and 5b over the entire surface. This serves to avoid undesired reactions between materials of the regions 5a and 5b and thus ensures improved stability of the charge carrier generation layer 5. A second organic functional layer stack S2 is arranged on the charge carrier generation layer 5. The second organically functional layer stack S2 comprises a second emitter layer 6, followed by an electron injection layer 7. The second emitter layer 6 is designed to emit light in the visible range of the electromagnetic spectrum during operation of the device. Finally, a cathode 8 is arranged on the electron injection layer 7. Such an organic electronic device 100 thus comprises at least two emitter layers, between which a charge carrier generation layer is arranged. It is possible to view such a device as a device composed of several OLEDs, wherein the first organic layer stack S1 forms a first OLED and the second organic layer stack S2 forms a second OLED over the charge carrier generation layer 5. The first OLED connected to anode 2 or the first organic functional layer stack Si is supplied with positive charge carriers by the anode 2, while it is supplied with electrons, thus negative charge carriers, by the charge carrier generation layer 5. In the same way, the second OLED or the second organic functional layer stack S2 is supplied with electrons by the cathode 8 via the charge carrier generation layer 5, while it receives the required positive charge carriers from the charge carrier generation layer 5. Such organic electronic devices offer the advantage that for each positive or negative charge carrier injected into the device, two rather than just one exciton can be generated. The same current thus leads to a higher light output, but at the expense of a higher applied voltage. The voltage is increased due to the voltage drop along the series-connected OLEDs.

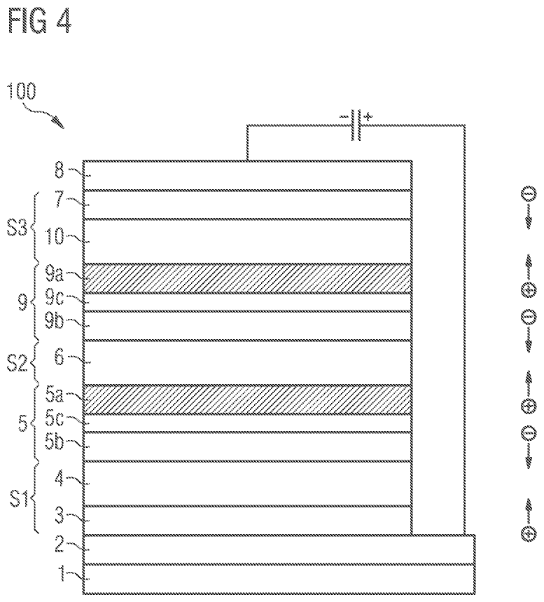

FIG. 4 schematically shows a further embodiment of an organic electronic device 100. The device 100, as shown in FIG. 4, is similar in all essential properties to the device of FIG. 3, but the second organic functional layer stack S2 has only the second emitter layer 6. In addition to the device shown in Figure 3, the device 100 in FIG. 4 additionally has a second charge carrier generation layer 9, which in turn has an organic p-doped region 9a and an n-conducting region 9b. In addition, it again has an intermediate region 9c. The regions 9a, 9b and 9c are preferably in turn configured as layers. With regard to the possible materials and other embodiments, the same choice applies to them as for the regions 5a, 5b and 5c. In addition, the device in FIG. 4 has a third organic layer stack S3 comprising a third emitter layer 10 and an electron injection layer 7. The charge carrier generation layer 9 is arranged between the second organic layer stack S2 and the third organic layer stack S3.

Such a device with at least three emitter layers has the advantage that it can be used to achieve particularly high color intensities with the same current intensity. It is possible, for example, that all three emitter layers emit electromagnetic radiation of the same wavelength. In this case, it is possible to generate particularly high luminances at this wavelength. However, it is preferred that the three emitter layers emit electromagnetic radiation of different spectral ranges, that is to say of different wavelengths. In this way, color mixtures can be formed by the overlapping of the light of the different wavelength ranges. In particular, it is possible in this way to produce white light according to a preferred embodiment.

FIG. 5 illustrates a schematic representation of an embodiment of an organic electronic device loft The device 100 has a substrate 1, for example, made of glass. On the substrate 1, an anode 2 is arranged, which consists, for example, of indium tin oxide. On the anode 2, a first organic functional layer stack Si is arranged. The layer stack S1 has a hole injection layer 3 arranged above the anode 2. Over the hole injection layer 3 is disposed an electron blocking layer 11, followed by a first emitter layer 4. Over the first emitter layer 4, a hole blocking layer 12 is arranged. A charge carrier generation layer 5 is arranged above the first organic functional layer stack S1. The charge carrier generation layer 5 consists of a p-doped organic region 5a, an intermediate region 5c and an n-conducting region 5b. The n-conducting region 5b is arranged in direct mechanical contact with the first functional layer stack S1. The intermediate layer 5c is connected to the areas 5a and 5b over the entire surface. This serves to avoid undesired reactions between materials of the regions 5a and 5b and thus ensures improved stability of the charge carrier generation layer 5. A second organic functional layer stack S2 is arranged on the charge carrier generation layer 5. The second organically functional layer stack S2 has a further electron blocking layer 13 and a second emitter layer 6 arranged above it. Above the second emitter layer 6, a further hole blocking layer 14 and above an electron injection layer 7 are arranged. Above the second organic functional layer stack S2, a cathode 8 is arranged. Such an organic electronic device thus comprises at least two emitter layers, between which a charge carrier generation layer is arranged. The emitter layers are adapted to emit light during operation of the device. Also, this device can be considered analogous to those of FIG. 3 or 4, a composite of several OLEDs devices.

Organic electronic devices, as shown in FIGS. 3, 4 and 5, are also often referred to as so-called tandem OLEDs. Organic electronic devices based on this design principle are characterized by a significantly higher luminance at the same current compared to conventional OLEDs. This leads to significantly longer lifetimes and at the same time to an improved homogeneity of the luminous surface.

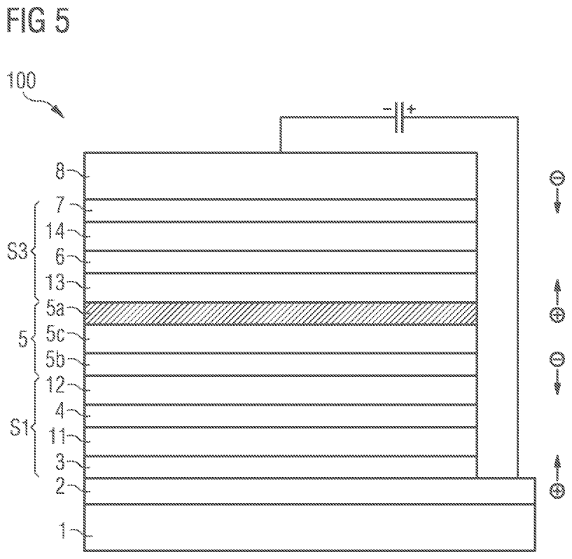

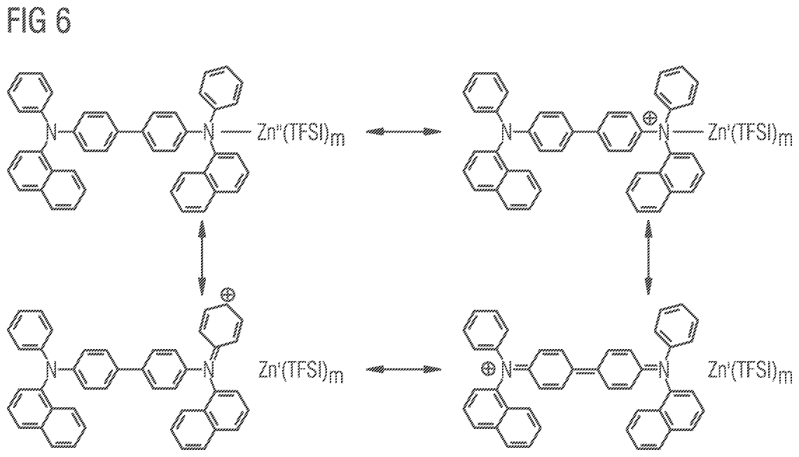

FIG. 6 shows the formation of a positive charge and its delocalization using the example of the hole-conducting matrix material NPD and the example of the fluorinated sulfonimide metal salt Zn (TFSI)m as p-type dopant. The sulfonimide anions are abbreviated as TFSI and their number is simply abbreviated to m. The hole can be transferred from one to the next NPD molecule by the so-called hopping mechanism. A conductivity path is advantageous, but not absolutely necessary because of the possible hopping mechanism. The coordination number of zinc may change during charge transfer, for example, by releasing a TFSI ligand. The aromatic hole transporter as matrix material can also bind via a p-bond to the metal of the fluorinated sulfonimide metal salt.

The zinc complex as p-type dopant serves merely as an example and is not intended to be limiting. The mechanism can also be transferred to other fluorinated sulfonimide metal salts. It can be seen in FIG. 6 that the fluorinated sulfonimide metal salt coordinates or binds to the matrix material and thus transfers a positive charge to the matrix material. The fluorinated sulfonimide metal salt can cleave again leaving the positive charge localized on the matrix material. The lower right and left structural formulas of FIG. 4 show a mesomerized stabilization of the positively charged matrix material. The charge is thus freely movable within the matrix molecule and can be forwarded by the so-called hopping mechanism to the next matrix molecule. Only a few percent, in particular ≥1 vol. % to ≤20 vol. % of the fluorinated sulfonimide metal salt is necessary to produce a free positive charge carrier, so holes or electron deficits in the hole-conducting matrix material, in particular an organic light-emitting diode.

The matrix material, in this case the hole-conducting matrix material NPD, can also bind to M of the metal salt via a π-bond.

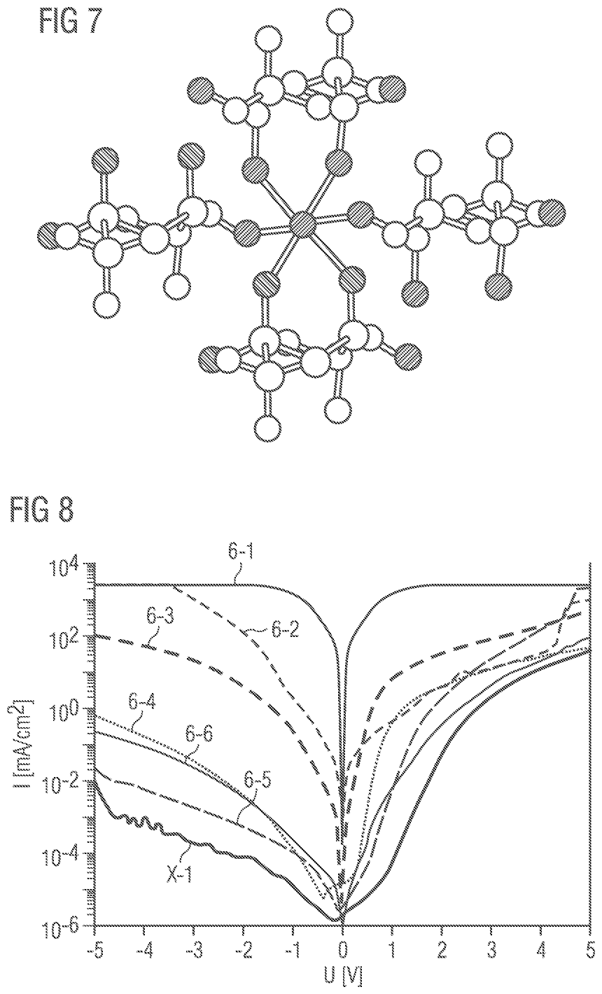

FIG. 7 shows the spatial arrangement of a fluorinated sulfonimide metal salt according to one embodiment. Zinc di[bis(trifluoromethylsulfonyl)imide] (CAS number: 168106-25-0) is shown. The coordination possibilities of the sulfonimide anion to the metal zinc are shown. The sulfonimide anions bind therein both chelating via two oxygen atoms and simply via only one oxygen atom. In this example, four sulfonimide ligands bind to only one zinc(II) center. This would lead to a double negative charge. However, the singly bounded sulfonimide ligands can bind to another zinc center, resulting in the sum of a kind of coordination polymer of the formula [Zn(TFSI)2]n. In the layer, this polymer is completely or partially split by the hole-conducting matrix material. This is simply reproduced in this application as Zn(TFSI)2. Depending on the metal, a bond of N or S of the sulfonimide to the metal is also conceivable. Due to the large number of metals in the periodic table, there is a high degree of structural diversity. The choice of the metal with its charge also influences the number of single negatively charged sulfonimide anions, in particular the TFSI anion, the sublimation temperature, the solubility and the doping strength. Thus, these parameters are adjustable within wide limits and can be adapted to the desired type of processing, for example, the liquid processing, or the vacuum deposition as well as to various hole transport materials.

The fluorinated sulfonimide metal salts are characterized by a high thermal stability and are available in particular for vacuum processing. FIG. 7 shows the coordination of the perfluoroalkylsulfonimides to the metal, for example, zinc. The sulfonimides can be chelating coordinated via two oxygen atoms to the central atom copper.

FIG. 8 shows conductivity measurements on hole-conducting matrix materials doped with fluorinated sulfonimide metal salt according to embodiments of the invention.

A first important prerequisite for the suitability of a dopant for use in a p-doped organic region within a charge carrier generation layer is that the dopant has a sufficient p-type dopant strength and enables good hole conductivities in the doped region. Only then can the positive charges generated in the charge carrier generation layer be efficiently dissipated and injected into the adjacent region. Therefore, the p-type dopant strengths of the fluorinated sulfonimide metal salts were investigated.

FIG. 8 shows a current-voltage characteristic according to several embodiments and comparative examples. In each case the current density in mA/cm² is shown as a function of the voltage U in V. The fluorinated sulfonimide metal salt serves as p-type dopant and HTM014 serves as a hole-conducting matrix material. In particular, the proportion of the fluorinated sulfonimide metal salt is 15 vol.-%. The matrix material has a proportion of 85 vol.-%.

The curve X-1 shows the current-voltage characteristic of the matrix material HTM014 without addition of a p-type dopant. The curves 6-1 to 6-6 each show a current-voltage characteristic of the p-type dopant, fluorinated sulfonimide metal salt, in the matrix material HTM014. The following fluorinated sulfonimide metal salts were used as p-type dopant:

Curve 6-1: copper di[bis(trifluoromethylsulfonyl)imide] Cu(TFSI)₂,
Curve 6-2: Potassium [bis(trifluoromethylsulfonyl)imide] K(TFSI),
Curve 6-3: zinc di[bis(trifluoromethylsulfonyl)imide] Zn(TFSI)₂,
Curve 6-4: Magnesium [bis(trifluoromethylsulfonyl)imide] Mg(TFSI)2. The curve 6-5: Lithium [bis(trifluoromethylsulfonyl)imide] Li(TFSI)
Curves 6-6: sodium [bis(trifluoromethylsulfonyl)imide] Na(TFSI).

The current-voltage characteristics are recorded intrinsically. From the group of divalent or higher valent metals with an atomic mass of >26 g/mol, the characteristics of Zn(TFSI)₂ and Cu(TFSI)₂ are shown by way of example. By doping into the hole-conducting matrix material HTM014, both materials produce almost symmetrical characteristics with a very strong increase in the current density at very low voltages. This indicates an efficient charge injection from both electrodes and thus a very strong doping effect. As a comparative example, the current-voltage characteristic of Mg(TFSI)₂ is listed. With this lighter element with an atomic mass of <26 g/mol, no efficient doping is achieved.

From the group of monovalent metals with an atomic mass of ≥39 g/mol, the current-voltage characteristic of K(TFSI) is shown, for example. By doping into the hole-conducting matrix material HTM-014, an almost symmetrical characteristic with a very strong increase in the current density at very low voltages is obtained. This indicates an efficient charge carrier injection from both electrodes and thus a very strong doping effect. As a comparative example, the characteristics of Na(TFSI) and Li(TFSI) are listed. With these lighter elements with an atomic mass of <39 g/mol, no efficient doping is achieved.

The effectiveness of the p-type dopant is attributed to its Lewis acidity. In particular, the corresponding acids of the fluorinated sulfonimide metal salts have a pKa value greater than −3, preferably greater than 0. These are not super acids. Two- or higher-valent metals have a higher Lewis acidity due to their higher oxidation state, which is why even lighter metals with an atomic mass of >26 g/mol are suitable as a p-type dopant. Monovalent metals, on the other hand, are less Lewis acidic and thus suitable only as p-type dopant with an atomic mass ≥39 g/mol. The atomic mass also increases the atomic number and thus the number of protons in the atomic nucleus. The higher the number of protons, the easier it is for an atom to absorb an additional electron. Therefore, only metal salts with a certain sufficient high atomic mass are suitable.

### Preparation of Fluorinated Sulfonimide Metal Salts

### 1. Purification of Zinc Bis(Trifluoromethanesulfonimide), Zn(TFSI)2

Zn(TFSI)2 (CAS: 168106-25-0) is commercially available from Sigma-Aldrich. The solid was sublimed under high vacuum. The initial weight is 800 mg, the weight out 156 mg. The temperature is 174 to 178° C. at a pressure of about 5·10⁻⁶ mbar. The product was obtained as a white amorphous solid.

### 2. Purification of Copper Bis(Trifluoromethanesulfonimide), Cu(TFSI)2

Cu(TFSI)2.xH2O (CAS: 1334406-76-6) is commercially available from Sigma-Aldrich. The solid was sublimed twice under high vacuum. The first sublimation was carried out with an initial weight of 580 mg and a weight out of 331 mg at a temperature of 115 to 145° C. The product was obtained as a white amorphous solid. The second sublimation was carried out at a weight of 331 mg and a weight of 266 mg at a temperature of 115 to 145° C. The product was obtained as a white amorphous solid.

### 3. Purification of Lithium Trifluoromethanesulfonimide, Li(TFSI)

Li(TFSI) (CAS: 90076-65-6) is commercially available from Sigma-Aldrich. The solid was distilled twice under high vacuum. The first distillation was carried out with an initial weight of 1.2 g and a weight out of 0.92 g. The white Li (TFSI) is liquid at 225 to 230° C. and distilled at 250 to 270° C. as a white amorphous solid. The second distillation was carried out with an initial weight of 0.92 g and a weight out of 0.40 g and a temperature of 250 to 270° C. The product is obtained as a white amorphous solid.

### 4. Purification of Sodium Trifluoromethanesulfonimide, Na(TFSI)

Na(TFSI) (CAS: 91742-21-1) is commercially available from Sigma-Aldrich. The solid was distilled twice under high vacuum. The first distillation was carried out with an initial weight of 505 mg and a weight out of 410 mg. The white Na(TFSI) is liquid at 265° C. and distilled at 270-295 ° C. as a white, partially crystalline solid. The second distillation was carried out with an initial weight of 410 mg and a weight out of 270 mg and a temperature of 270 to 275° C. The product is obtained as a white solid.

### 5. Purification of Potassium Trifluoromethanesulfonimide, K(TFSI)

K(TFSI) (CAS: 90076-67-8) is commercially available from Sigma-Aldrich. The solid was distilled twice in a high vacuum in a ball tube (Kugelrohr). The first distillation was carried out at an initial weight of 482 mg and a weight out of 366 mg. The white K(TFSI) is liquid at 205° C. and distilled at 270 to 290° C. The second distillation was carried out at a weight of 366 mg and a weight of 241 mg at a temperature of 270 to 285° C.

### 6. Reference Device With Intrinsic Matrix Material, HTM-014

A reference system, a so-called majority charge carrier device (single-carrier device), has been set up. The device has a substrate 1 made of glass. The substrate 1 is followed by an anode 2 made of ITO (indium tin oxide). The anode 2 is followed by an organic layer comprising a matrix material of HTM-014. The organic layer has a layer thickness of approximately 200 nm. The organic layer 3 is followed by a cathode 8 made of aluminum. Two devices with 15 pixels each and a pixel area of 4 mm2 were produced.

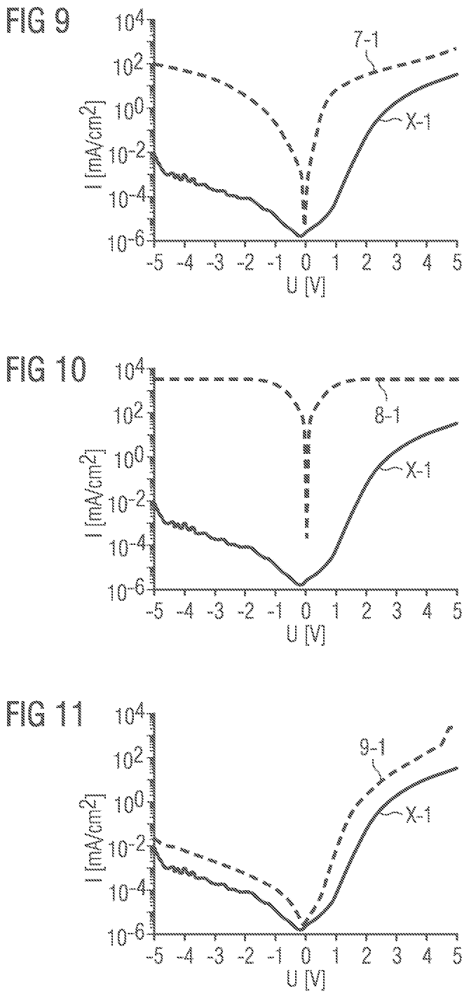

FIGS. 9 to 11 show the current-voltage characteristics of this corresponding reference device as a solid characteristic x-1.

### 7. Doping the Matrix Material HTM-014 With Zn(TFSI)2

FIG. 9 shows the current-voltage characteristic of the reference device x-1 (solid line) and an embodiment 7-1 (dashed line). The current density I in mA/cm2 is shown as a function of the voltage U in V. The organic electronic device is a majority charge carrier device. In order to demonstrate the doping effect in this device, it has glass as substrate 1, as anode 2 ITO, a 200 nm thick organic layer 3 of a matrix material HTM-014 doped with 15 vol.-% Zn(TFSI)2 and a cathode 8 of aluminum. Two devices with 15 pixels each and a pixel area of 4 mm2 were produced.

It can be seen from FIG. 9 that the doping has an effect on the current-voltage characteristic. The current density in the doped layer increases strongly above and below 0 V, while for the intrinsic undoped layer (solid line), a typical diode characteristic is observed in which a significant build-in voltage is required before the current density increases. Moreover, this is the case with the intrinsic layer only at positive voltages, while the doped layer also shows increased current densities at negative voltages and also allows efficient electron injection from the anode 2 (ITO).

### 8. Doping the Matrix Material HTM-014 With Cu(TFSI)2

To demonstrate the doping effect, a majority charge carrier device was built with the following architecture:

Glass substrate 1,
ITO as anode 2,
200 nm HTM-014 doped with 15 vol. % Cu(TFSI)₂ as organic layer 3,
Aluminum as cathode 8.

Two devices with 15 pixels each and a pixel area of 4 mm2 were produced.

FIG. 10 shows, as dashed line 8-1, the current-voltage characteristic of this exemplary embodiment. It can be shown that the doping has a very strong effect on the current-voltage characteristic. The current density increases very strongly in the doped layer above and below 0 V and at a voltage >1 V, quickly reaches the maximum current density which was set during the measurement in order to protect the device against excessive currents. The current-voltage characteristic shows that Cu(TFSI)₂ is an extremely strong p-type dopant.

### 9. Doping the Matrix Material HTM-014 with Li(TFSI)

FIG. 11 shows the current-voltage characteristic of a comparative example. To demonstrate the low doping effect, a majority charge carrier device with the following device architecture was constructed:

Glass substrate 1,
ITO as anode 2,
200 nm HTM-014 doped with 15 vol. % Li(TFSI) as organic layer,
Aluminum as cathode 9.

Two devices with 15 pixels each and a pixel area of 4 m2 were produced.

The dashed characterisitc 9-1 of FIG. 11 shows the current-voltage characteristic of this structure. It can be shown that the doping with lithium trifluoromethylsulfonimide is less efficient and has almost no effect on the current-voltage characteristic. The current density in the doped layer is only very slightly higher than the current density in the undoped reference device. Also, for example, the doping of spiro-MEOTAD with 12 vol.-% Li(TFSI) shows only a conductivity increase of two orders of magnitude (κ=0 2*10-5 S/cm). This corresponds to a low to moderate doping effect. Due to the low doping effect with lithium trifluoromethylsulfonimide this dopant is excluded according to embodiments of the invention.

The excellent conductivity properties demonstrated in FIGS. 9 and 10 form a necessary but not sufficient prerequisite for the suitability of the fluorinated sulfonimide metal salts according to embodiments of the invention in charge carrier generation layers of organic electronic devices.

In addition to the conductivity a second property must be added, that the complexes must be suitable to allow a tunnel current at the p-n junction of a charge carrier generation layer.

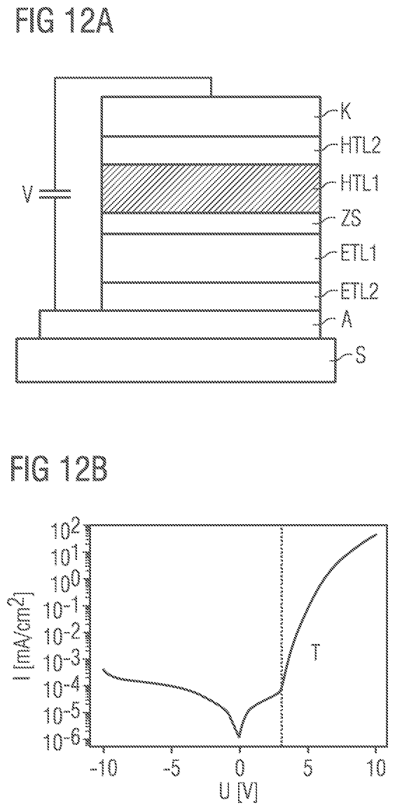

FIG. 12A shows a test arrangement with which this question can be examined. The test arrangement of FIG. 12A simulates the polarity of a tandem OLED. It requires a p-type dopant and allows the determination of whether a p-type dopant is suitable for use in a charge carrier generation layer. The test assembly has a glass substrate S followed by an indium tin oxide anode A, followed by an electron transporting layer ETL 2 having a thickness of 25 nm. This is followed by an electron-transporting layer ETL 1 of 50 nm thickness with n-type doping. This is followed by the intermediate layer ZS and finally the hole-transporting layer HTL 1 to be tested. The intermediate layer ZS in the present case is a 4 nm thick phthalocyanine derivative layer. The hole-transporting layer HTL 1 having a thickness of 50 nm is doped with the p-type dopant to be tested. The layer can be obtained, for example, by co-evaporation of the hole-conducting matrix material with the p-type dopant. This layer is followed by a hole transporting layer HTL 2 with 25 nm thickness. The conclusion is the cathode K. The electron- or hole-transporting layer ETL 2 or HTL 2 have a significantly lower electron or hole conductivity than ETL 1 or HTL 1. Their function in this arrangement is to stretch the current voltage characteristic with respect to the voltage. The arrangement described allows p-type dopants to be tested whether they enable good tunnel currents.

FIG. 12B shows a theoretical, ideal curve for a p-dopant suitable for the p-doped region of a charge carrier generation layer. The curve shows for high positive voltages a significant increase in the current density, which is attributed to the so-called tunneling effect. Conventional p-type dopants which are not suitable for charge carrier generation layers show no or very low tunnel currents T. A corresponding current-voltage curve does not look like in FIG. 12B: The high positive current densities at positive potentials are not given, instead the graph is symmetrical when viewed around an axis—applied at 0 V.

In the case of the occurrence of high tunnel currents T one also speaks of the so-called “CGL effect” (CGL=charge generation layer effect). The occurrence of the tunnel current, that is to say the CGL effect, thus represents a decisive criterion for the suitability of a p-type dopant for charge carrier generation layers. In contrast to most conventional p-type dopants, the fluorinated sulfonimide metal salts according to embodiments of the invention surprisingly exhibit a significant CGL effect in the presence of an intermediate layer.

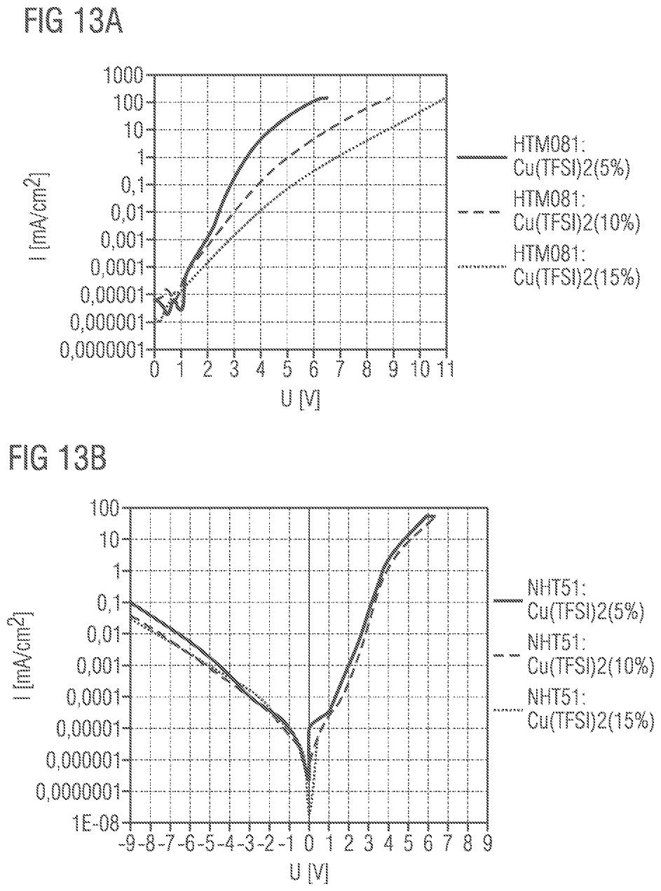

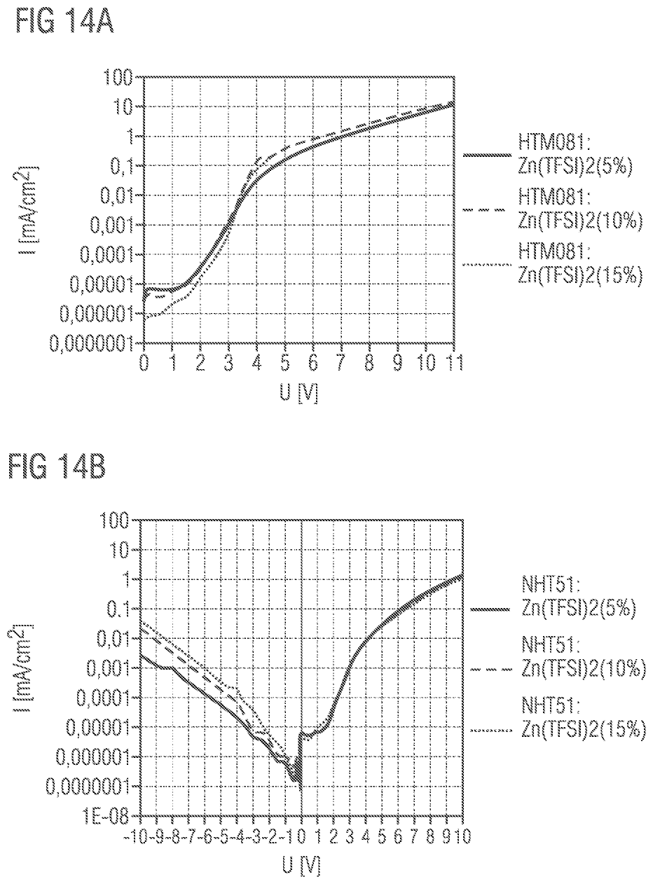

FIGS. 13A, 13B, 14A and 14B show current-voltage characteristics for devices with the fluorinated sulfonimide metal salts according to embodiments of the invention. The current density I in mA/cm2 is shown as a function of the voltage U in V in each case. The measurements were carried out in each case in the measuring arrangement described in FIG. 12A, wherein the fluorinated sulfonimide metal salts being introduced into the HTL 1 layer as p-type dopant. HTM081 from Merck and NHT51 from Novaled were used as hole-conductor matrix materials. These matrix materials were used because a tunnel current does not occur with these materials without p-type dopant. Thus, the tunnel current occurring in the measurements is due in each case to the p-type dopant according to embodiments of the invention or to the combination of the applied matrix material with the p-type dopant according to embodiments of the invention. In each case results for Cu(TFSI)₂ are shown in FIGS. 13A and 13B and for Zn(TFSI)₂ in FIGS. 14A and 14B, the concentration of which in the matrix material is given in each case in percent by volume. Measurements are shown for 5, 10 and 15 vol. % based on the p-doped layer. The measurements in FIGS. 13A and 13B as well as 14A and 14B clearly demonstrate the occurrence of high tunnel currents for the fluorinated sulfonimide metal salts according to embodiments of the invention in a broad concentration range. A strong CGL effect could thus be clearly demonstrated, in particular because tunnel currents do not occur when using the matrix materials without or without suitable p-type dopant. With the p-type dopants according to embodiments of the invention a tunnel current can be generated, which is not possible with all p-type dopants suitable for the conductivity doping. Thus, the p-type dopants according to embodiments of the invention prove to be an alternative to commercially available from Novaled p-type dopant NDP9, which is a purely organic dopant and shows a similar strong CGL effect. In addition, Zn(TFSI)₂ and Cu(TFSI)₂ are commercially and cost-effectively available as hydrates. As described above, the Zn(TFSI)₂ as well as Cu(TFSI)2 can be easily prepared from the hydrates by dehydration.

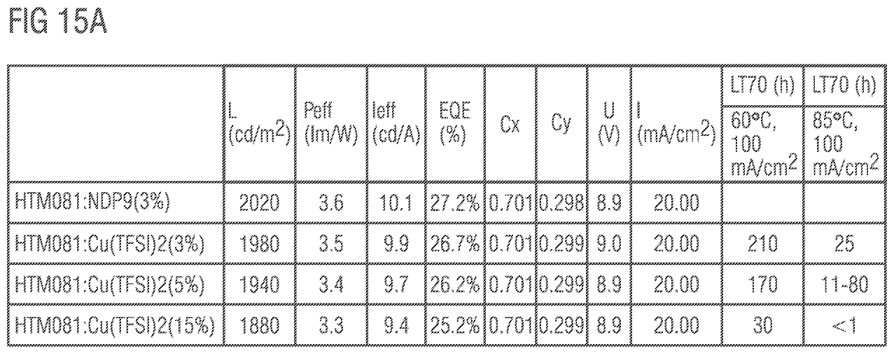

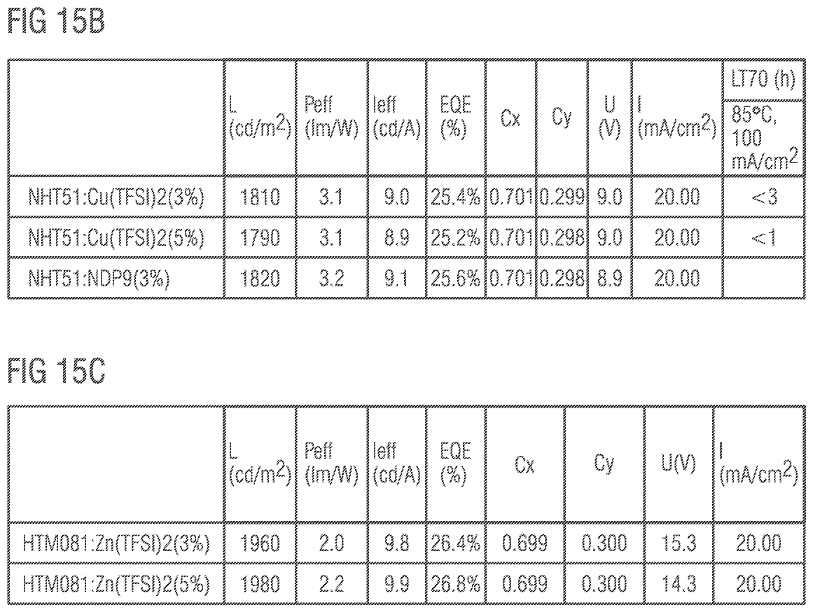

FIGS. 15A, 15B and 15C show characteristic properties of organic electronic devices according to embodiments of the invention and comparative examples (with NDP9 as p-type dopant). These properties were determined by means of a test arrangement according to FIG. 5. As anode 2 a 130 nm thick ITO layer was used and a cathode 8 made of aluminum with a layer thickness of 200 nm was used. During operation of the device, the first emitter layer 4 and the second emitter layer 6 emit light in the red spectral region and have identical structures. The organic p-doped region 5a has a layer thickness of 105 nm and consists in each case of the matrix material and p-dopant indicated in the tables.

In the tables of FIGS. 15A, 158 and 15C, L denotes the luminance, Peff the light output, Ieff the power efficiency, EQE the external quantum efficiency, Cx and Cy the coordinates of the emitted radiation in the CIE color space, U the applied voltage, I the current density , LT70 indicates the period of time after which the luminance L has dropped to 70 percent of its initial value at the specified conditions (at 60° C., 100 mA/cm² or at 85° C., 100 mA/cm²). In the first column is in each case the matrix material (HTM081 or NHT51) and the p-type dopant (Cu(TSFI)₂ or Zn(TSFI)₂) or NDP9 (comparative example) and proportion in percent by volume are given. In particular, the tested devices are characterized by the fact that only a voltage of about 9 volts must be applied to achieve a current density I of 20 mA/cm². Without p-type dopant or without suitable p-type dopant, a voltage of more than 20 V is necessary to achieve such current densities.

The described fluorinated sulfonimide metal salts thus enable the required tunnel currents and at the same time fulfill all other requirements such as processability, stability and also sufficiently low absorption of the doped layers. It is thus a p-type dopant of a new substance class for charge carrier generation layers.

In summary, it can be said that the fluorinated sulfonimide metal salts according to embodiments of the invention allow high p-type dopant strengths in hole-conducting matrix materials and thus excellent hole transport properties. At the same time, they allow high tunnel currents, thus a strong CGL effect to be achieved at p-n transitions in charge carrier generation layers. Furthermore, they are characterized by low absorption and, at the same time, outstanding optical properties for use in organic electronic devices, also in the field of optoelectronics.

The invention is not limited by the description with reference to the embodiments. Rather, the invention encompasses each novel feature as well as each combination of features, which includes in particular each combination of features in the patent claims, even if this feature or this combination itself is not explicitly indicated in the patent claims or exemplary embodiments.

1-13. (canceled)

14. An organic electronic device comprising:
a first organic functional layer stack;
a second organic functional layer stack; and
a charge carrier generation layer arranged therebetween, the charge carrier generation layer comprising:
an n-conducting region;
an organic p-doped region; and
an intermediate region arranged therebetween with a layer thickness of 0.1 nm to 20 nm,
wherein the organic p-doped region has as a p-type dopant a fluorinated sulfonimide metal salt of the following formula 1: 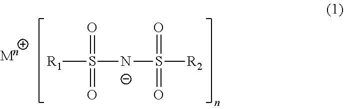
wherein M is either a divalent or higher-valent metal having an atomic mass of greater than 26 g/mol or a monovalent metal having an atomic mass of greater than or equal to 39 g/mol,
wherein 1≤n≤7, and
wherein R₁ and R₂ are independently selected from a group consisting of a fluoro-substituted aryl residue, a fluoro-substituted alkyl residue and a fluoro-substituted arylalkyl residue.

15. The organic electronic device according to claim 14, wherein M is copper, zinc, aluminum, bismuth, potassium, rubidium, cesium, scandium, yttrium or tin.

16. The organic electronic device according to claim 14, wherein R₁ and R₂ are independently selected from a group consisting of a linear or branched at least partially fluoro-substituted alkyl residue of 1 to 10 carbon atoms, an at least partially fluoro-substituted aryl residue of 1 to 20 carbon atoms and an at least partially fluoro-substituted arylalkyl residue of 1 to 20 carbon atoms.

17. The organic electronic device according to claim 14, wherein R₁ and R₂ are the same substituents and are selected from the group consisting of:

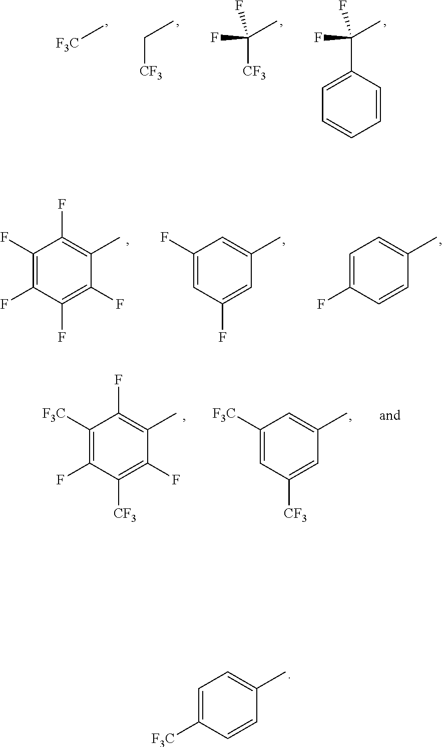

18. The organic electronic device according to claim 14, wherein the fluorinated sulfonimide metal salt has the following formula 2:

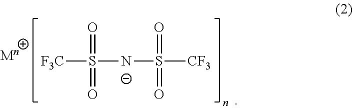

19. The organic electronic device according to claim 14, wherein the organic p-doped region has an organic hole-conducting matrix in which the p-type dopant is incorporated.

20. The organic electronic device according to claim 14, wherein a proportion of the fluorinated sulfonimide metal salt based on the organic p-doped region of 1 vol. % to 20 vol. %.

21. The organic electronic device according to claim 14, wherein the n-conducting region is an n-doped region.

22. The organic electronic device according to claim 14, wherein the intermediate region comprises an insulating, organic or inorganic material.

23. The organic electronic device according to claim 14, wherein the intermediate region comprises a phthalocyanine and/or a phthalocyanine derivative.

24. The organic electronic device according to claim 14, wherein the organic electronic device is an organic diode, an organic field effect or bipolar transistor, an organic photodetector, an organic solar cell or an organic electrochemical cell.

25. The organic electronic device according to claim 14, wherein the organic electronic device is an organic light-emitting diode, and wherein the organic first functional layer stack comprises a first emitter layer and the second organic functional layer stack comprises a second emitter layer.

26. The organic electronic device according to claim 14, further comprising at least one further organic functional layer stack and at least one further charge carrier generation layer.
